(19) United States
(12) Patent Application Publication
(10) Pub. No.: US 2023/0159823 A1
(43) Pub. Date: May 25, 2023

(54) HALIDE PEROVSKITE NANOCRYSTALS

(71) Applicant: THE ROYAL INSTITUTION FOR THE ADVANCEMENT OF LEARNING/MCGILL UNIVERSITY, Montréal (CA)

(72) Inventors: Masoud AMINZARE, Montréal (CA); Sara MAHSHID, Mont-Royal (CA); Noémie-Manuelle DORVAL COURCHESNE, Montréal (CA)

(21) Appl. No.: 18/056,900

(22) Filed: Nov. 18, 2022

Related U.S. Application Data
(60) Provisional application No. 63/281,121, filed on Nov. 19, 2021.

(51) Int. Cl. C09K 11/66; C30B 29/12; C01G 21/00

(52) U.S. Cl. CPC C09K 11/664; C30B 29/12; C01G 21/006; C01P 2002/34

(57) ABSTRACT

There is provided a protein-halide perovskite nanocrystal (p-HPNC) comprising: a crystalline core of halide perovskites and an outer layer made of protein surrounding the crystalline core. The protein has a net positive electric charge at a pH of 3 or less in its free state. The protein is linked to the surface of the crystalline core, and the halide perovskites have a formula ABX₃, where A is a monovalent cation, B is a divalent cation, and X is a monovalent halide anion.

### CROSS-REFERENCE TO A RELATED APPLICATION

The present application claims the priority of U.S. provisional application No. 63/281,121 filed on Nov. 19, 2021, which is incorporated herein by reference in its entirety.

### TECHNICAL FIELD

This disclosure relates to the field of halide perovskite nanocrystals, more specifically suspensions of halide perovskite nanocrystal colloids, methods of making same, and uses thereof.

### BACKGROUND OF THE ART

Over the last decade, halide perovskites (HPs) have garnered interest due to their optoelectronic properties. Although most investigations have been mainly focused on improving and optimizing photovoltaics (PV), light emitting diodes (LEDs) and photodetectors efficiencies of HPs, there is great interest and potential towards biological and biomedical applications (e.g. biosensors, bioimaging). The extreme moisture instability and toxicity of lead HPs in aqueous environment are still major obstacles for their practical usages in humid conditions and bio-applications. Heat and light also cause instability of lead HPs. To address these challenges, the development of aqueous synthesis routes is imperative, and will lead to several benefits for the fabrication of HPs, including easy scale up, economic viability, environmentally friendliness as well as new applications which require aqueous media. However, the strong ionic nature and the weak interactions between the organic and inorganic constituents are mainly responsible for the rapid decomposition of HPs upon exposure to water. Therefore, organic solvents such as dimethylformamide (DMF), dimethyl sulfoxide (DMSO) and toluene together with hydrophobic organic ligands, have been extensively used for HPs synthesis to provide basic protection in humid environments. These are somewhat environmentally harmful substances and are inappropriate for commercial scale up and bio-applications. Surface encapsulation in dense polymer layers or metal oxides is an alternative way to encounter the water instability of HPs, nevertheless these extra layers introduce additional complexities in the fabrication process and deteriorate HPs optoelectrical properties. Besides, the encapsulated particles exist in the form of powder suspensions and struggle with partial agglomeration, which restrict HPs applications in optoelectronics, biology, and catalysis.

It has been determined that the presence of water can be beneficial for the formation of HPNCs and thin films. Eperon et al. revealed that an increase in atmospheric humidity lowers the continuity of the HP thin films but enhances the rate of film formation and improves photoluminescence (PL) properties and overall PV performances. Trap densities in the films are reduced by surface reaction with water molecules, which originate from partially surface solvation and self-healing of the perovskite lattice. Currently water stable HPs are large (several micrometres), with a wide PL full width at half-maximum (FWHM) of 40-50 nm and low photoluminescence quantum yield (PLQY %) of below 12% for MAPbBr₃ and 54% for CsPbBr₃ materials. Therefore, the chemistry of formation of HPs, the control over their peripheral layer, and the appropriate tuning of optical properties in aqueous conditions need further and in-depth explorations. Most significantly, a recent report (Geng et al.) successfully challenged the direct aqueous synthesis and stabilization of HP nanocrystals (HPNCs) by proper adjustment of solubility equilibrium of CH₃NH₃PbX₃ (X═Br or Cl/Br) nanocrystals, [PbX₆]⁴⁻ and CH₃NH₃⁺ ions in aqueous solution, while keeping all the process under acidic pH in the range of 0-5. They suggested that excessive halogen ions in the acidic region as well as protonated methylamine drive the reaction between methylamine and [PbX₆]⁴⁻ towards the creation of CH₃NH₃PbX₃ and obstruct the formation of PbX₂ or Pb(OH)₂ as byproducts of HPs decomposition, and lower-dimension HPs can also be fabricated in water media. For instance, bright yellow one-dimensional (1D) hybrid HP micro-belts [(AD)Pb₂Cl₅] (AD=acridine) have been fabricated in aqueous solution under ambient condition by Yang et al. It has been claimed that solid electrostatic, hydrogen bond and π-π stacking interactions of AD cations lead to the formation of a dense organic water-resistant layer, which inhibits the reaction of the inorganic layer with water molecules providing a steric hindrance for long-term stability under humid conditions and in water.

In parallel, functional ligands have been applied as powerful agents to facilitate assembly of HPNCs and enhance their optoelectronic properties. Among them, it is vital to explore the interaction of HPs with biomolecules and comprehend the influence of biomolecules on HPs stability and optoelectrical properties. There have been few studies that disclosed the advantages of implementation of biomolecules such as amino acids and peptides for the formation, stabilization and physical properties enhancement of HP nanocrystals and thin films. Shih et al. demonstrated that various amino acids can trigger preferential orientation of HP crystals, increase surface trap passivation, and facilitate charge transfer efficiency at TiO₂/CH₃NH₃PbI₃ interface leading to a maximum 30% (by using 1-alanine) power conversion efficiency boost in HP solar cells. Lang et al. reduced the dissolution rate of MAPbBr₃ crystals in water and improved their resistance to humidity by incorporating amino acids into the crystal lattice. Among different amino acids, lysine was best suited to replace the two MA⁺ ions (up to 1 mol %) and operate as a “molecular bridge” that holds the atoms strongly together in the host crystal structure due to its two NH₃⁺ groups. Also, lysine influenced the lattice parameter, optical band gap as well as thermal properties and morphology of the inserted MAPbBr₃. As another example, trifunctional L-cysteine was applied as a capping ligand for the self-assembly of cubic supercrystals of HPNCs through a wet chemistry method, which resulted in about 7 times enhancement of PLQY % and lifetime as well as stability of the as synthesized capped supercrystals. Wang et al. claimed that robust interactions between the L-cysteine ligands and the HPNCs originate from synergistic effects between amino, carboxylic and sulfhydryl groups could control the self-assembly process by cross-linking and hinder the HPNCs agglomeration. Likewise, Geng et al. added phenylalanine (PLLA) amino acid to enhance the stability, the degree of dispersion of HPNCs, as well as their PLQY % up to 40% in an aqueous solution. Apart from single amino acids, peptides with unique biological functions are also of interest, and their combinations with HPs have brought remarkable opportunities for the development of bio active HPNCs. As an example, commercial cyclic peptide Cyclo(RGDFK), comprising 5 amino acids has been employed as a surface stabilizer for the synthesis of sub-10 nm MAPbBr₃ HPNCs in a form of colloidal dispersion in chloroform. The Cyclo(RGDFK) passivate HPNCs surface in a way that the guanidyl group of the peptide is directed towards the outside, which cause the electrons transfer from the peptide shell in the direction of the perovskite core. This configuration was found as not suitable for achieving high PLQY % but as beneficial for charge transfer sensitive applications (i.e. sensors) (Prochazkova et al.).

Moving to a higher degree of biological complexity and potential functionalities, proteins are ubiquitous molecular building blocks in nano- and biotechnology. They possess a high affinity for the surfaces of variety of solid materials such as metals, metal oxides, polymers, minerals, etc. and are capable of mediating the fabrication of nanostructures. Improvements in the performance and stability halide perovskite nanocrystals in an aqueous phase are thus desired with biocompatible modifications such as protein additions.

### SUMMARY

In one aspect, there is provided a protein-halide perovskite nanocrystal (p-HPNC). The p-HPNC has a crystalline core of halide perovskites and an outer layer made of protein surrounding the crystalline core. The protein has a net positive electric charge at a pH of 3 or less in its free state. The protein is linked to the surface of the crystalline core. The halide perovskites have a formula ABX₃, where A is a monovalent cation, B is a divalent cation, and X is a monovalent halide anion.

The p-HPNC can be linked to the crystalline core by at least one of hydrogen bonds, π-π stacking, van der Waals bonds, and electrostatic interactions. The protein layer can be a capping layer and the protein is a capping protein. The p-HPNC may be defined by one or more of the following features: a full width at half-maximum (FWHM) of from 10 to 50 nm, the protein having a molecular weight of from 500 Da to 500 kDa, the protein having an isoelectric point pI in the range of 3-12 preferably 3.5-5.5, a size of 5 to 50 nm, X being one of is I⁻, Br or Cl⁻, having a crystalline core that is a cubic phase or a tetragonal phase.

In one aspect, there is provided an aqueous colloidal suspension comprising p-HPNC colloids, the p-HPNC being as defined in the present disclosure. The aqueous colloidal suspension has a pH of less than 7, preferably equal to or less than 6.

In one aspect, there is provided a method of producing an aqueous colloidal suspension comprising p-HPNC colloids, the method comprising: mixing in an acidic aqueous solution a divalent cation B, a monovalent halide anion X, and a protein, to obtain a dispersion comprising the divalent cation B, the monovalent halide anion X, and the protein; mixing in the dispersion a monovalent cation A, and increasing the pH of the dispersion to obtain the p-HPNC colloids and the aqueous colloidal suspension. A is preferably selected from Cs⁺, CH₃NH₃⁺, and CH(NH₂)₂⁺. X is selected from Br⁻, I⁻ and Cl⁻. B is preferably selected from Pb²⁺, Sn²⁺, and Ge²⁺. The acidic aqueous solution can have a pH of less than 3. The method may be performed at ambient conditions of temperature and pressure.

In one aspect, there is provided an imaging method comprising, irradiating the aqueous colloidal suspension of the present disclosure with a light irradiation, and measuring the photoluminescence.

In one aspect, there is provided the use of the p-HPNC of the present disclosure for in imaging and optoelectronics.

Many further features and combinations thereof concerning the present improvements will appear to those skilled in the art following a reading of the instant disclosure.

### DESCRIPTION OF THE DRAWINGS

FIG. 1A is a schematic showing a fully aqueous formation of protein-capped HPNCs.

FIG. 1B is an X-ray diffraction spectra showing the intensity in function of 2e for bovine serum albumin-stabilized HPNCs (BSA-HPNCs);

FIG. 1C is a photoluminescence (PL) spectra (λₑₓ=405 nm) and UV-Vis absorption spectra showing the photoluminescence intensity and absorbance in function of the wavelength;

FIG. 1D is a Tauc plot from the UV-Vis spectra of FIG. 1C;

FIG. 1E is a graph of PL or spectra thereof in function of the wavelength of bovine serum albumin halide perovskite nanocrystals (BSA-HPNCs (●)) and pure halide perovskites (pure-HPs (▴));

FIG. 1F is a graph of UV-Vis absorption or spectra thereof in function of the wavelength for BSA-HPNCs (●) and pure-HPs (▴);

FIG. 1G is a Tauc plot from the UV-Vis spectra of FIG. 1F;

FIG. 1H is a graph of PL in function of the decay time;

FIG. 1I is a transmission electron microscopy (TEM) image of a protein halide perovskite according to an embodiment of the present disclosure (scale bar 20 nm);

FIG. 1J is a transmission electron microscopy (TEM) image of a protein halide perovskite according to an embodiment of the present disclosure (scale bar 5 nm);

FIG. 1K is a graph showing the size distribution of the halide perovskite produced according to an embodiment of the present disclosure;

FIG. 1L is a scanning electron microscopy (SEM) image of HPs synthesized with no protein;

FIG. 1M is a SEM image of the HPs of FIG. 1K at a smaller magnification;

FIG. 1N is a transmission electron microscopy (TEM) image of a protein halide perovskite according to an embodiment of the present disclosure (scale bar 20 nm);

FIG. 1O is a TEM image of a protein halide perovskite according to an embodiment of the present disclosure (scale bar 100 nm);

FIG. 1P is an TEM X-ray spectrometer (EDX) spectra showing the counts (a.u.) in function of energy (keV);

FIG. 1Q is a graph showing a graph of the distance distribution function derived from small-angle X-ray scattering (SAXS) data;

FIG. 1R shows a graph of the thermographic measurements (weight % in function of temperature) for the bovine serum albumin (BSA)-halide perovskite nanocrystals (HPNC) complex, HP, and BSA;

FIG. 1S shows a graph of the thermographic measurements (weight % in function of temperature) for the bovine serum albumin (BSA)-halide perovskite nanocrystals (HPNC) complex, HP, and BSA;

FIG. 1T shows a graph of the thermographic measurements (weight % (solid line) and deriv. weight % (dashed line) in function of temperature) for BSA;

FIG. 1U shows a graph of the thermographic measurements (weight % (solid line) and deriv weight % (dashed line) in function of temperature) for pure HP;

FIG. 1V shows a graph of the thermographic measurements (weight % (solid line) and deriv weight % (dashed line) in function of temperature) for BSA-HPNC;

FIG. 1W shows a graph of X-ray photoelectron spectroscopy (XPS) of intensity (a.u.) in function of the binding energy for BSA-HPNC;

FIG. 1X shows Fourier transformer infrared (FTIR) spectra for pure HPS, BSA, and BSA-HPNCs (top line to bottom line respectively);

FIG. 1Y shows a graph of the PL intensity in function of the wavelength for BSA-HPNCs produced with different amounts of BSA: no BSA (▴), 5 mg (Δ), 10 mg (♦), 15 mg (⋄), 20 mg (□), 40 mg (●), and 50 mg (□);

FIG. 1Z is a graph of maximum PL intensity (●) in function of the protein content and the PLQY changes (♦) with the amount of protein;

FIG. 2A shows a graph of X-ray photoelectron spectroscopy (XPS) of intensity (a.u.) in function of the binding energy for a sample without HP;

FIG. 2B shows a graph of X-ray photoelectron spectroscopy (XPS) of intensity (a.u.) in function of the binding energy for pure HP with the values as measured, the curve fit, the values for the first bromine signal, the value for the second bromine signal, and background;

FIG. 2C shows a graph of X-ray photoelectron spectroscopy (XPS) of intensity (a.u.) in function of the binding energy for pure HP with the values as measured, the curve fit, the values for the first, second, third, and fourth lead signals, and background;

FIG. 2D shows a graph of X-ray photoelectron spectroscopy (XPS) of intensity (a.u.) in function of the binding energy for pure HP with the values as measured, the curve fit, the values for the first, and second carbon signals, and background;

FIG. 2E shows a graph of X-ray photoelectron spectroscopy (XPS) of intensity (a.u.) in function of the binding energy for pure HP with the values as measured, the curve fit, the values for oxygen signal, and background;

FIG. 2F shows a graph of X-ray photoelectron spectroscopy (XPS) of intensity (a.u.) in function of the binding energy for pure HP with the values as measured, the curve fit, the values for nitrogen signal, and background;

FIG. 2G shows a graph of time-resolved photoluminescence decay curves of BSA-HPNCs as a function of BSA content, the time-correlated single-photon counting (TCSPC) data were fitted with biexponential functions using the DAS06 software from Horiba™;

FIG. 3A shows a graph of X-ray photoelectron spectroscopy (XPS) of intensity (a.u.) in function of the binding energy for BSA-HPNC with the values as measured, the curve fit, the values for the first bromine signal, the value for the second bromine signal, and background;

FIG. 3B shows a graph of X-ray photoelectron spectroscopy (XPS) of intensity (a.u.) in function of the binding energy for BSA-HPNC with the values as measured, the curve fit, the values for the first, and second lead signals, and background;

FIG. 3C shows a graph of X-ray photoelectron spectroscopy (XPS) of intensity (a.u.) in function of the binding energy for BSA-HPNC with the values as measured, the curve fit, the values for the first, second and third carbon signals, and background;

FIG. 3D shows a graph of X-ray photoelectron spectroscopy (XPS) of intensity (a.u.) in function of the binding energy for BSA-HPNC with the values as measured, the curve fit, the values for the first, second and third oxygen signals, and background;

FIG. 3E shows a graph of X-ray photoelectron spectroscopy (XPS) of intensity (a.u.) in function of the binding energy for BSA-HPNC with the values as measured, the curve fit, the values for first and second nitrogen signal, and background;

FIG. 4A shows a graph of the absorbance in function of the wavenumbers for BSA sample;

FIG. 4B shows a graph of the absorbance in function of the wavenumbers for BSA-HPNC sample;

FIG. 5A shows a graph of the PL intensity in function of the wavelength for BSA-HPNC at a pH of 1, 2, 3, 4, 5, and 6;

FIG. 5B shows a graph of the relative PL intensity in function of the pH at values of 1, 2, 3, 4, 5, and 6 as provided in FIG. 5A;

FIG. 5C shows a graph of the PL intensity in function of the wavelength for BSA-HPNC at a pH of 6, 6.25, 6.5, 7, and 7.25;

FIG. 5D shows a graph of the relative PL intensity in function of the pH at values of 6, 6.25, 6.5, 7, and 7.25 as provided in FIG. 5C;

FIG. 5E shows an XRP pattern graph of the intensity in function of 2e for BSA-HPNC at a pH of 7, 6.5, 6.25, 6, 5, 4, 3, 2, 1 and the reference (respectively from the top line to the bottom line);

FIG. 5F shows a graph of the zeta potential in function of the pH for BSA-HPNC and BSA;

FIG. 5G shows a schematic diagram of the formation of a protein-HPNC colloid in an aqueous phase;

FIG. 5H shows a graph of the photoluminescence intensity of BSA-HPNC in function of time for a duration of 50 hours;

FIG. 5I shows a graph of the photoluminescence intensity of BSA-HPNC in function of time for a duration of 120 days;

FIG. 6A is a photograph of a colorimetric assay to track HPNCs formation kinetics (first day);

FIG. 6B is a photograph of a colorimetric assay to track HPNCs formation kinetics (second day);

FIG. 6C is a photograph of a colorimetric assay to track HPNCs formation kinetics (fourth day)

FIG. 7A is a XRD graph of the intensity in function of 2e for, from line top to line bottom, BSA-MAPbI₃, BSA-MAPbI₃ reference, BSA-MAPbBr₃, BSA-MAPbBr₃ reference, BSA-MAPbCl₃ and BSA-MAPbCl₃ reference;

FIG. 7B shows a graph of the normalized photoluminescence intensity (●) and the UV-vis absorption (∘) in function of the wavelength for BSA-MAPbCl₃, BSA-MAPbBr₃, and BSA-MAPbI₃ as identified on the graph;

FIG. 7C shows a graph of the decay of photoluminescence in function of time for BSA-MAPbCl₃, BSA-MAPbBr₃, BSA-MAPbI₃ and the instrument response factor (IRF).

FIG. 7D is a graph of the PL intensity in function of the wavelength for CsPbBr₃ and FAPbBr₃.

FIG. 8A shows XRD patterns for HPNC formed with pepsin, lysozyme, hemoglobin, trypsin, casein, and BSA (respectively the lines from top to bottom);

FIG. 8B shows a FTIR spectra of HP, BSA-HPNC, Casein-HPNC, Hemoglobin-HPNC, Trypsin-HPNC, Lysozyme-HPNC, and Pepsin-HPNC respectively from the top line to the bottom line;

FIG. 8C shows UV-Vis absorption spectra of HPNCs synthesized with casein, BSA, Trypsin, Hemoglobin, Lysozyme, and Pepsin;

FIG. 8D shows a PL spectra of HPNCs synthesized with casein, BSA, Trypsin, Hemoglobin, Lysozyme, and Pepsin (curves from top to bottom respectively) with a fixed protein:perovskite molar ratio;

FIG. 8E shows a PL spectra of HPNCs synthesized with casein, BSA, Trypsin, Hemoglobin, Lysozyme, and Pepsin (curves from top to bottom respectively) with a fixed protein:perovskite mass ratio;

FIG. 8F shows time-resolved photoluminescence decay curves of HPNCs with the proteins casein, BSA, Trypsin, Hemoglobin, Lysozyme, and Pepsin and the control IRF;

FIG. 8G shows a TEM image of Casein-HPNC;

FIG. 8H shows a TEM image of BSA-HPNC;

FIG. 8I shows a TEM image of Hemoglobin-HPNC;

FIG. 9A shows an FTIR spectra of MAPbBr₃ HPNCs synthesized with casein (bottom line), of casein alone (middle line), and HPs alone (top line);

FIG. 9B shows an FTIR spectra of MAPbBr₃ HPNCs synthesized with BSA (bottom line), of BSA alone (middle line), and HPs alone (top line);

FIG. 9C shows an FTIR spectra of MAPbBr₃ HPNCs synthesized with hemoglobin (bottom line), of hemoglobin alone (middle line), and HPs alone (top line);

FIG. 9D shows an FTIR spectra of MAPbBr₃ HPNCs synthesized with trypsin (bottom line), of trypsin alone (middle line), and HPs alone (top line);

FIG. 9E shows an FTIR spectra of MAPbBr₃ HPNCs synthesized with lysozyme (bottom line), of lysozyme alone (middle line), and HPs alone (top line);

FIG. 9F shows an FTIR spectra of MAPbBr₃ HPNCs synthesized with pepsin (bottom line), of pepsin alone (middle line), and HPs alone (top line);

FIG. 10A shows UV-Vis absorption and PL spectra of casein-HPNC;

FIG. 10B shows UV-Vis absorption and PL spectra of BSA-HPNC;

FIG. 10C shows UV-Vis absorption and PL spectra of hemoglobin-HPNC;

FIG. 10D shows UV-Vis absorption and PL spectra of trypsin-HPNC;

FIG. 10E shows UV-Vis absorption and PL spectra of lysozyme-HPNC;

FIG. 10F shows UV-Vis absorption and PL spectra of pepsin-HPNC;

FIG. 10G is a Tauc plot from the UV-Vis absorption of FIG. 10A;

FIG. 10H is a Tauc plot from the UV-Vis absorption of FIG. 10B;

FIG. 10I is a Tauc plot from the UV-Vis absorption of FIG. 10C;

FIG. 10J is a Tauc plot from the UV-Vis absorption of FIG. 10D;

FIG. 10K is a Tauc plot from the UV-Vis absorption of FIG. 10E; and

FIG. 10L is a Tauc plot from the UV-Vis absorption of FIG. 10F.

FIG. 11A shows the structure of bovine serum albumin (BSA).

FIG. 11B shows the structure of hemoglobin.

FIG. 11C shows the structure of pepsin.

FIG. 11D shows the structure of casein.

FIG. 11E shows the structure of trypsin.

FIG. 11F shows the structure of lysozyme.

### DETAILED DESCRIPTION

Halide perovskites (HPs) possess desirable optoelectronic properties, however their commercial usage has been restricted for many state of the art applications due to their rapid decomposition in the presence of water or under humid conditions. Paradoxically, the present disclosure provides an aqueous colloidal suspension of HPNCs and a method of aqueous synthesis of HPNCs, assisted by proteins as capping agents. Accordingly, the HPNCs of the present disclosure are protein-HPNCs (p-HPNCs) where an outer layer made of the protein surrounds the crystalline core of HPNCs. The halide perovskites of the present disclosure are of formula ABX₃, where A is a monovalent cation, B is a divalent cation and X is a monovalent halide anion. In some embodiments, A is methyl ammonium (MA) CH₃NH₃⁺, formamidinium (FA) CH(NH₂)₂⁺ or Cs⁺. Preferably, A is MA or FA. More preferably, A is MA. As used herein the terms methyl ammonium, protonated methylamine, MA, and CH₃NH₃⁺ are equivalent and interchangeable. In some embodiments, B is selected from Pb²⁺, Sn²⁺, and Ge²⁺. Preferably, B is Pb²⁺ or Sn²⁺. In some embodiments, X is Cl⁻, Br⁻, or I⁻. The colloidal suspension preferably has a pH between 1 and 7 to ensure the stability of the colloids in the aqueous phase and to limit or eliminate precipitations of the colloids. In some embodiments, the pH of the colloidal suspension can be between 1 and 7, from 1 to 6, from 2 to 6, between 3 to 7, between 3.5 to 7, between 4 to 7, from 3 to 6, from 3.5 to 6, from 4 to 6, from 3 to 6.5, from 3.5 to 6.5 or from 4 to 6.5.

In some embodiments, the p-HPNC colloids have a full width at half-maximum (FWHM) of from 10 to 50 nm, 20 to 50 nm, 30 to 50 nm, or 35 to 45 nm. The p-HPNC colloids may have a size of from 5 to 50 nm, from 5 to 30 nm, from 5 to 20 nm, less than 20 nm or less than 10 nm. In further embodiments, the protein has a molecular weight of from 500 Da to 500 kDa, from 1 kDa to 200 kDa, or from 10 kDa to 100 kDa. Accordingly, the present disclosure is not limited to specific proteins, and includes proteins of a wide range of molecular weights and isoelectric points to produce the p-HPNCs. Example proteins include but are not limited to bovine serum albumin (BSA), casein, hemoglobin, lysozyme, trypsin, and pepsin. The isoelectric point may be from 3 to 12, from 3 to 7, from 3.5 to 5.5, from 3.7 to 5.3, from 4.0 to 5.0 or from 4.3 to 4.7. The protein interacts with the crystalline core with at least one of hydrogen bonds, π-π stacking, van der Waals bonds, and electrostatic interactions. To promote the interaction between the crystalline core and the protein, the protein has a net positive electric charge. Furthermore, also to promote the interaction between the crystalline core and the protein, the protein may have a sufficient number of available functional groups such as amine groups and carboxylic groups. The interaction of the protein with the crystalline core is such that the protein will form an outer layer and act as a capping agent to promote the aqueous stability of the halide perovskite. The term “protein” as used herein refers to an amino acid containing molecule having at least one secondary structure such as an alpha helix, a beta sheet, beta barrel or beta helix. The term “protein” can be further defined by having at least one tertiary structure. In some embodiments, the protein in the outer layer of the p-HPNC substantially maintains its secondary and/or tertiary structures. The protein can be selected so as to confer the p-HPNC additional properties, for example the protein selected can have a biological effect. Further, the protein may be a recombinant protein engineered for a specific function to act in tandem with the optical properties of the p-HPNC.

The synthesized protein-mediated HPNCs exhibit high aqueous and colloidal stability and advantageous optical characteristics (i.e. lifetime, and full width at half-maximum (FWHM), etc.). The ionic balance and interaction of HPNCs with proteins prevent their decomposition in water for several weeks and improves the photoluminescence quantum yield (PLQY %) of the HPNCs up to 56% compared with unfunctionalized HPs (Pure-HPs). Indeed, proteins are generally water soluble and interact with the surface of the halide perovskite and provide chemical groups to stabilize them in water (e.g. carboxylic acid groups, amine groups and other polar/charged side amino acid side chains). The proteins passivate the surface of the halide perovskite, and provide a charged shell that maintains the colloids in suspension and prevent their aggregation. This protein-mediated synthesis strategy is also used to prepare Pb-free HPNCs functionalized with proteins as well as other biomolecules for many applications in biological and natural environments including cell imaging, environmental sensing, and the like.

The method of producing the aqueous colloidal suspension of the present disclosure comprises mixing in an acidic aqueous solution a divalent cation B, a monovalent halide anion X and a protein. The acidic aqueous solution has an acidic pH to maintain a dispersion and avoid the clumping or sedimentation of B, X, the protein or any complex formed with B, X and/or the protein. A monovalent cation A is mixed in the dispersion. The pH is increased to obtain the p-HPNC colloids and the aqueous colloidal suspension. When the monovalent cation A is basic the addition of a base may not be necessary to increase the pH (for example for MA and FA). When the monovalent cation A is not basic (for example Cs⁺) a base that will not interfere with the p-HPNC synthesis can be added to increase the pH (for example NaOH). The acidic aqueous solution can have a pH of less than 3, less than 2.5, less than 2, less than 1.5 or less than 1. The pH of the acidic aqueous solution will vary depending on the type of divalent cation B used. For example, lead is difficult to dissolve in water and would require a pH of less than 1.

The monovalent cation A, the divalent cation B and the monovalent halide anion X according to the present disclosure have atomic radii suitable for the formation of a halide perovskite as described further herein below. The formation and stability of perovskite structure can be determined by applying two semi-empirical factors (namely the Goldschmidt tolerance (t) factor and the octahedral factor (μ)) as per the equations below.

$$t = \frac{( {r}_{A} + {r}_{X} )}{\sqrt{2} ( {r}_{B} + {r}_{X} )} \qquad ( 1 )$$

$$μ = \frac{{r}_{B}}{{r}_{X}} \qquad ( 2 )$$

where r_{A}, r_{B}, and r_{X} are the ionic radii of the A-site, B-site, and X-site ions, respectively.
In the case where A is organic the tolerance factor is modified to the following equation:

$$t = \frac{{r}_{{A}_{e f f}} + {r}_{{X}_{e f f}}}{\sqrt{2} ( {r}_{B} + \frac{{h}_{{X}_{e f f}}}{2} )} \qquad ( 3 )$$

where r_{Aeff}, r_{Xeff}, and h_{Xeff} are the effective radius of the A-site cation, the effective radius, and length of the X-site anion, respectively.

The p-HPNCs formation and stabilization are controlled by a reaction between the B—X complex i.e. BX₂ (for example a lead halide complex) and the monovalent cation such as methylamine, together with proper adjustment of the pH, and the protein concentration, at ambient conditions. In some embodiments, at least 7.5 nmol/mL, from 7.5 to 100 nmol/mL, from 10 to 100 nmol/mL, from 20 to 100 nmol/mL or from 50 to 90 nmol/mL of protein can be provided to the acidic aqueous solution. Without wishing to be bound by theory, below 7.5 nmol/mL of protein provided, the resulting p-HPNC small particle size would have limited optical properties in aqueous conditions. Further, also without wishing to be bound by theory, the upper limit of the provided protein concentration is only limited by the reaction time (formation of the protein—HPNC colloid) and economical considerations for the production of the p-HPNCs. The method of the present disclosure can be performed at ambient conditions of temperature and pressure.

The p-HPNC and method according to the present disclosure is further described by the non-limitative experimental example herein below.

### Example

Precursors: All precursors were directly used as received without further modifications or purifications. PbI₂ (99% purity, Acros Organics), PbBr₂ (99% purity, Alfa Aesar), PbCl₂ (99% purity, Bio-Basic), HI (48% purity, ACP Chemicals), HBr (48% purity, Sigma-Aldrich), HCl (36-38% purity, Sigma-Aldrich), Methylamine solution (CH₃NH₂, 40 wt. % in water, Sigma-Aldrich), Distilled water, Casein (99% purity, Bio-Basic), BSA (98% purity, BioShop), Hemoglobin (From bovine blood, 98% purity, Sigma-Aldrich), Lysozyme (From egg white, 98% purity, Aladdin), Trypsin (Ultra pure, Bio-Basic), and pepsin (Ultra pure, Bio-Basic).

Synthesis of CH₃NH₃PbX₃ HPNCs: In a typical synthesis procedure, 0.1-2.5 mmol of PbX₂ (X═Cl, Br and I) is completely dissolved in HX solution (˜10-25 mmol) to make a transparent mother liquid solution. 1400 μL of the mother liquid solution was added in 8 mL of distilled water, followed by dropwise addition of the HX solution (600 μL) under stirring at ambient temperature to re-dissolve some precipitated out PbX₂. After the PbX₂ was fully dissolved, 75-750 nmol of a selected protein was applied on the slow stirring solution. The speed of mixing increased gradually until all protein was dispersed/dissolved. Next, up to 25 mmol of CH₃NH₂ aqueous solution was inserted into the solution under vigorous mixing until the desired pH (1-7) was achieved and maintained steady. The formed particles were collected by centrifugation for further analysis and the colloidal solutions were also kept for complementary characterizations.

Characterization: UV-Vis absorption and photoluminescence (PL) spectra were recorded with Thermo Scientific Evolution™ 300 UV-Vis and Horiba™ Flouromax-4 spectrophotometers. Small-angle X-ray scattering (SAXS) was conducted on the Anton Paar™ SAXSpoint 2.0 instrument with a Primux™ 100 micro-X-ray source (Cu Kα radiation (wavelength, λ=1.54 Å)) and a detector of Eiger™ R 1M (Horizontal). Transmission electron microscopy (TEM) studies were performed with a FEI Tecnai™ G2 F20 200 kV Cryo-STEM microscope operated at 200 kV. TEM X-ray spectrometer (EDX) was used for the determination of elemental chemical composition. X-ray diffraction (XRD) measurements were performed with a Bruker™ D8 Discovery X-ray Diffractometer (VANTEC Detector, Cu-Kα). Fourier transform infrared (FTIR) spectroscopy was carried out on PerkinElmer™ FTIR spectrometer (Spectrum One, spectral resolution 2 cm⁻¹). Thermogravimetric (TGA) measurements were performed with a TA-Instruments SDT Q-500 system at a heating rate of 5° C. min⁻¹. Zeta potential measurements were performed with a Malvern™ Panalytical Zetasizer Nano ZS analyzer. The X-ray photoelectron spectroscopy (XPS) were recorded with a ThermoFisher ESCALAB™ 250 Xi instrument with an Al Kα source. Steady-state spectra were recorded on a FluoroLog⁻³ spectrofluorometer from Horiba™ Scientific. Time-Correlated Single Photon Counting (TCSPC) experiments were carried out with the same instrument using a DeltaHub TSCPC controller and samples were excited with DeltaDiode™ 100 MHz laser (476 nm and 373 nm) also from Horiba™ Scientific. Solid spectra (both steady-state and TCSPC) were obtained directly on the powders held by a homemade powder holder cuvette. The Lifetime analysis were carried out using DAS06 software from Horiba™ scientific. The data were fitted with double exponentials function given by, I(t)=Σᵢ₌₁²Aᵢexp(−t/τᵢ), where Aᵢ is the amplitude of the PL decay component corresponding to of the lifetime τᵢ. The average lifetime (τ_{avg}) the samples was calculated using the following relationship: τ_{avg}=Σᵢ₌₂²Aᵢτᵢ²/Σᵢ₌₁²Aᵢτᵢ. Also, the PLQY % of MAPbBr₃ HPNCs was calculated by utilizing the following equation:

$$P L Q Y = P L Q {Y}_{s t} \frac{{F}_{x}}{{F}_{s t}} \frac{{A}_{s t}}{{A}_{x}}$$

where the subscript x and st represent the sample and standard, respectively. Flourescein (Sigma-Aldrich, 95% PLQY) was used as the standard. F is the integrated PL intensity, and A is the absorbance.

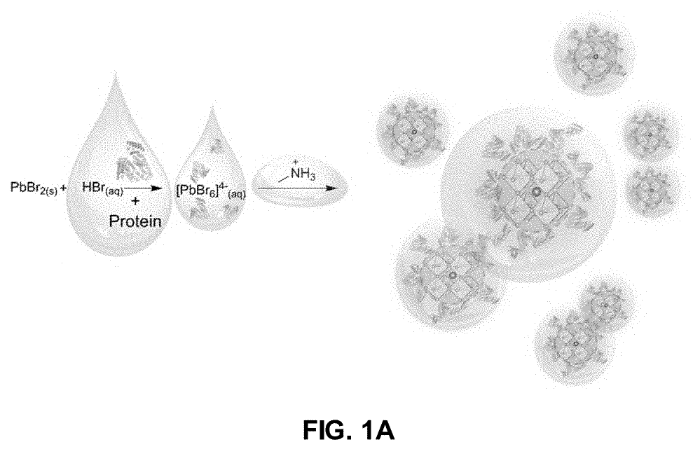

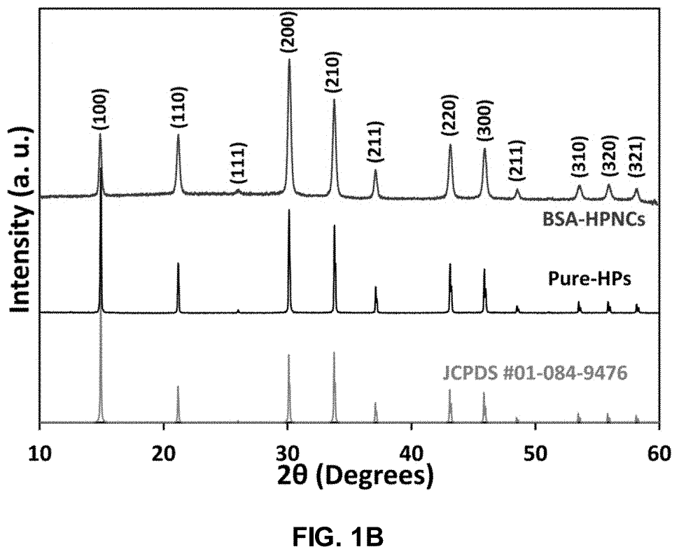

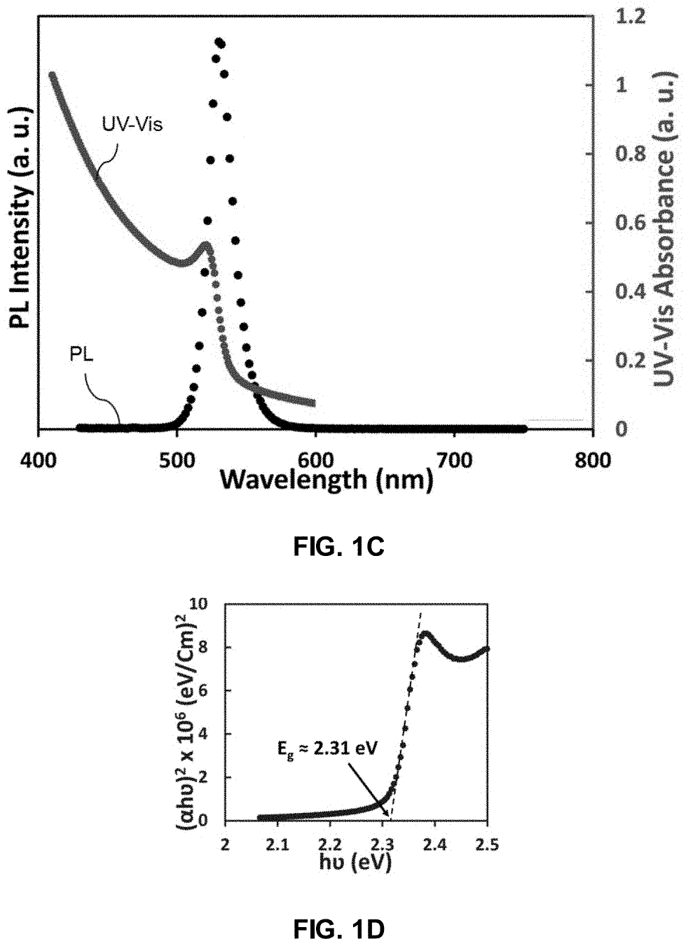

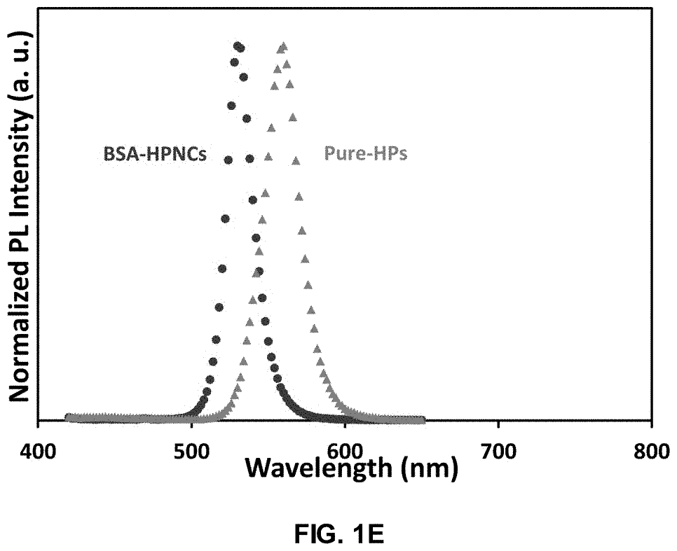

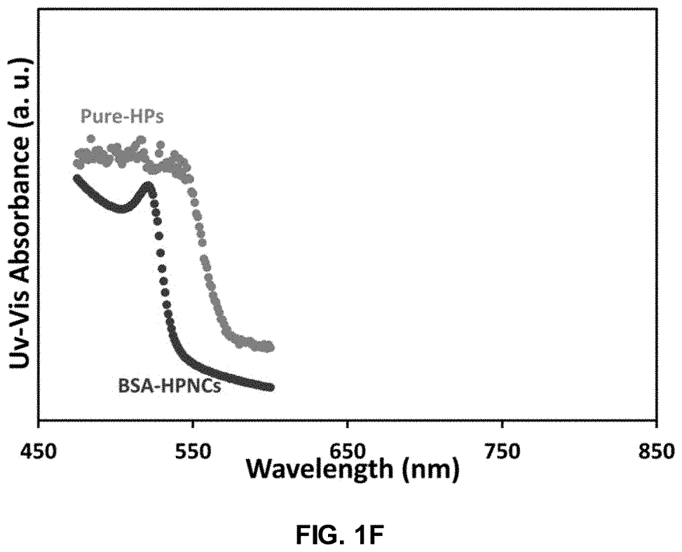

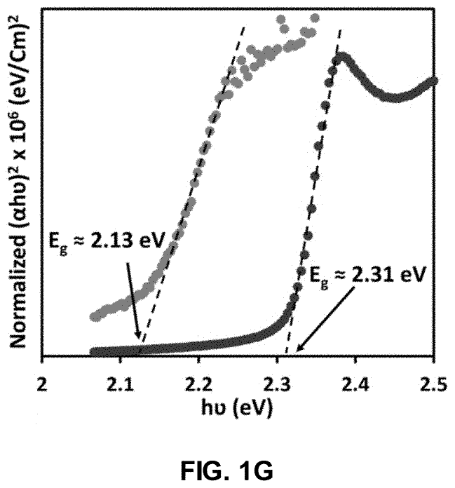

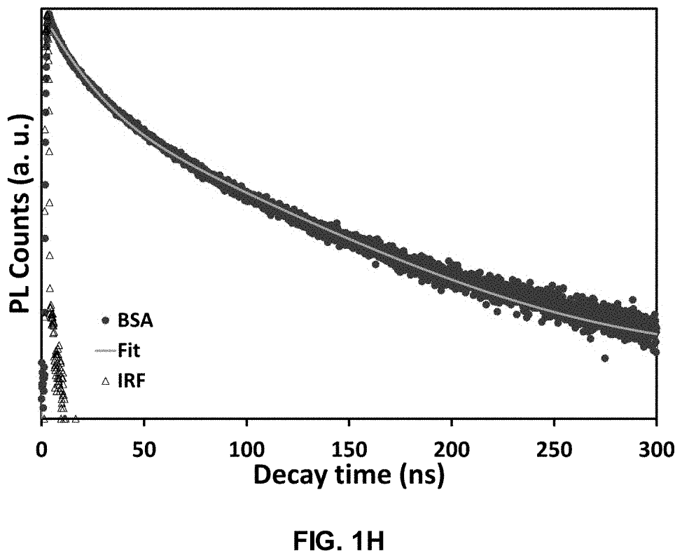

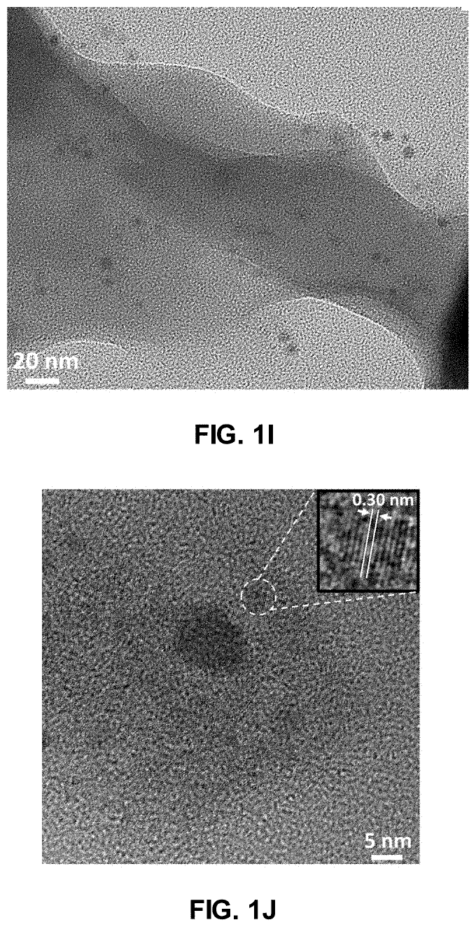

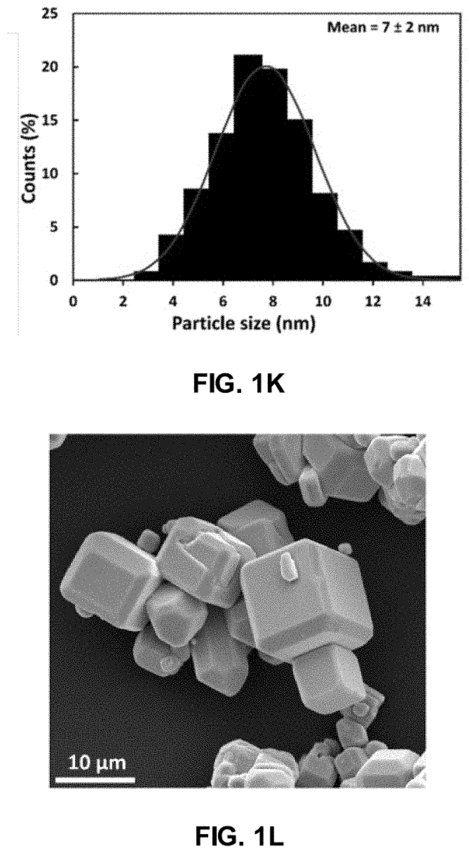

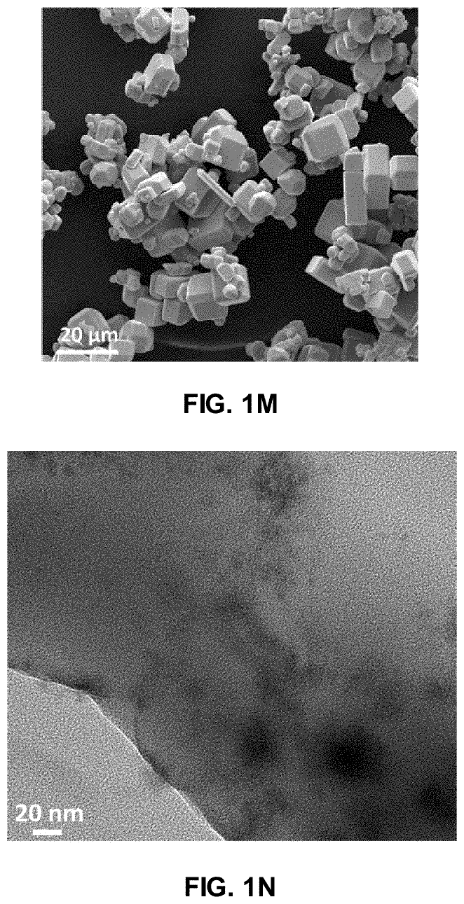

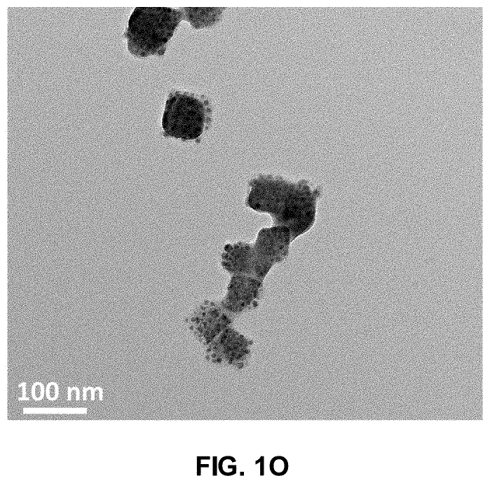

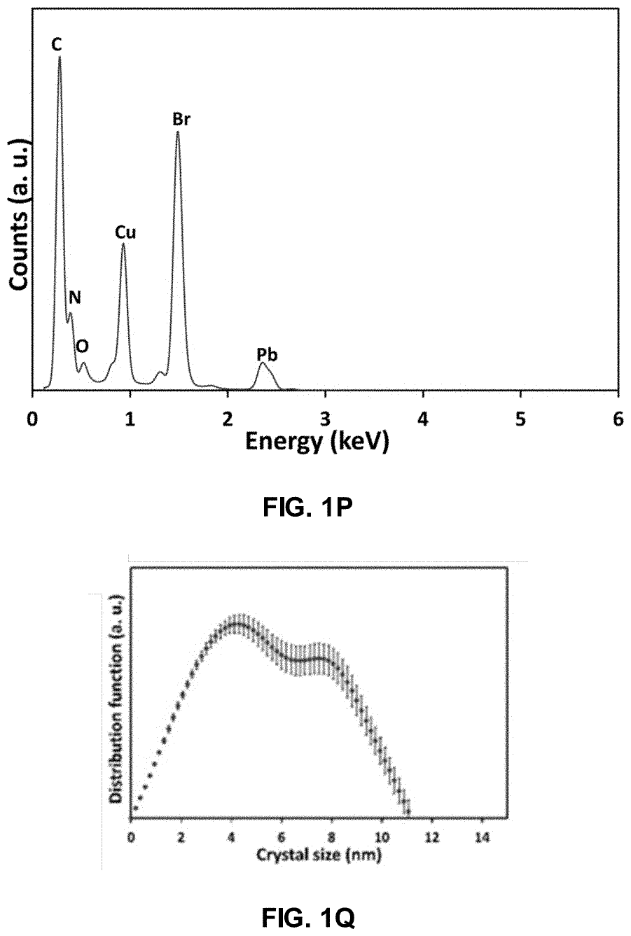

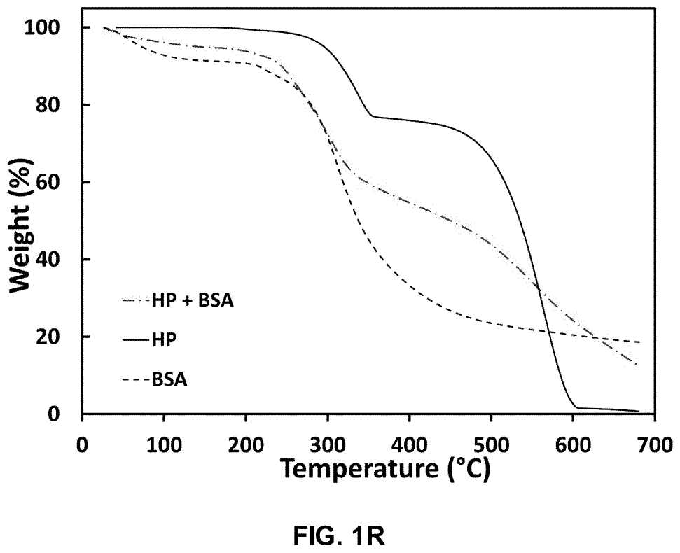

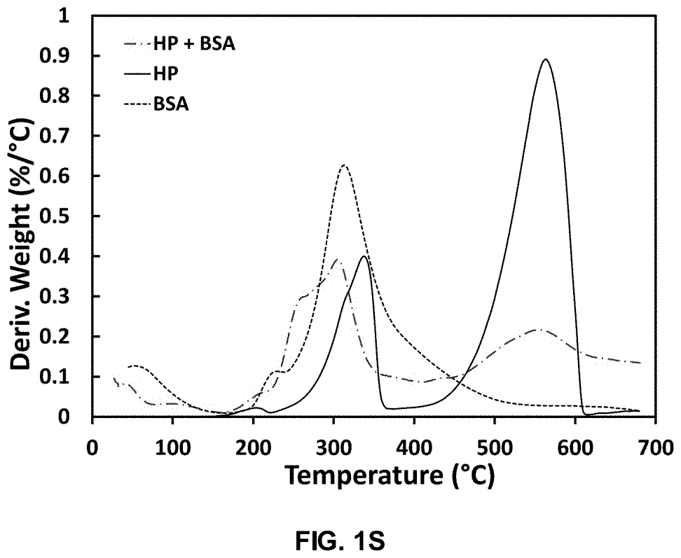

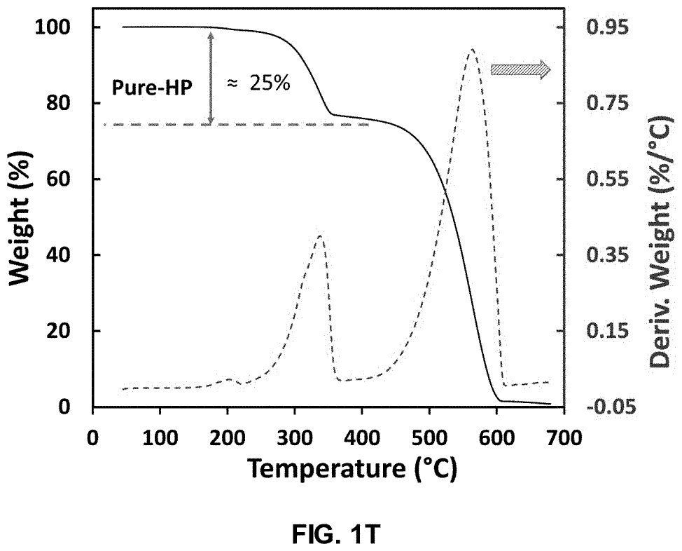

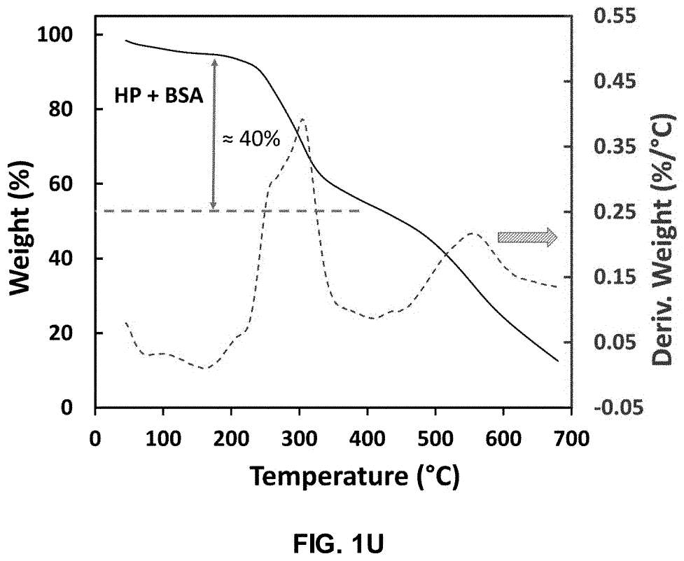

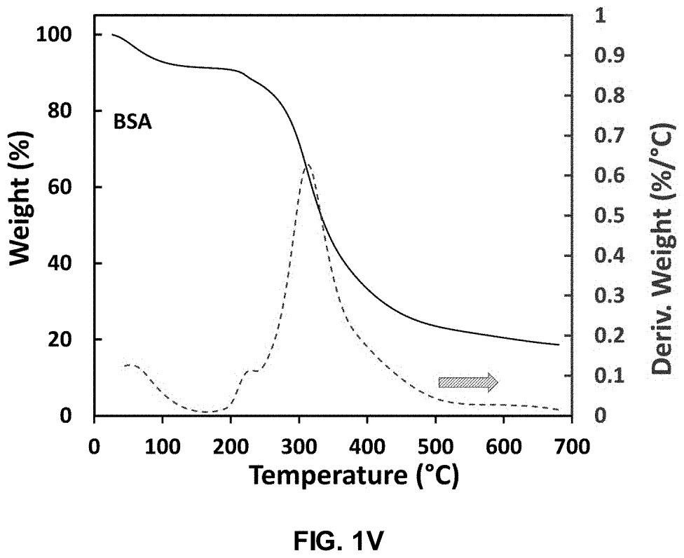

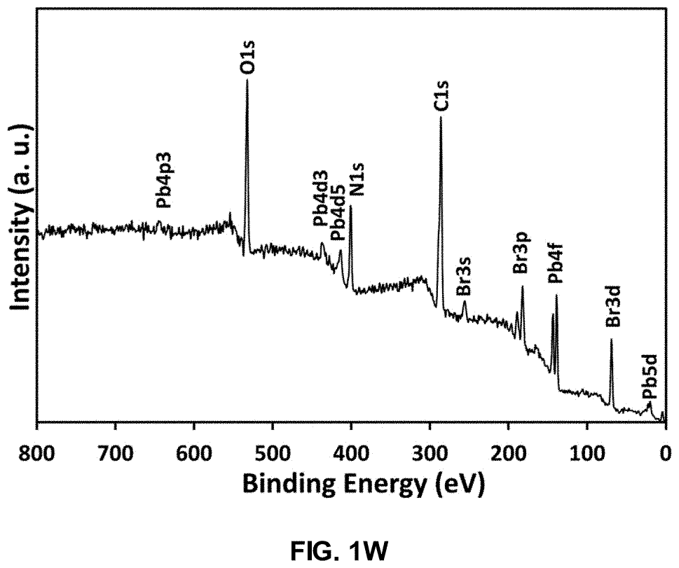

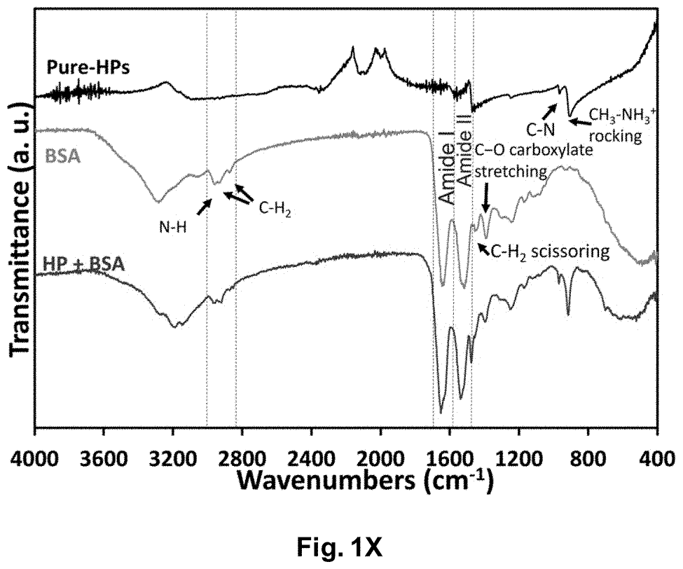

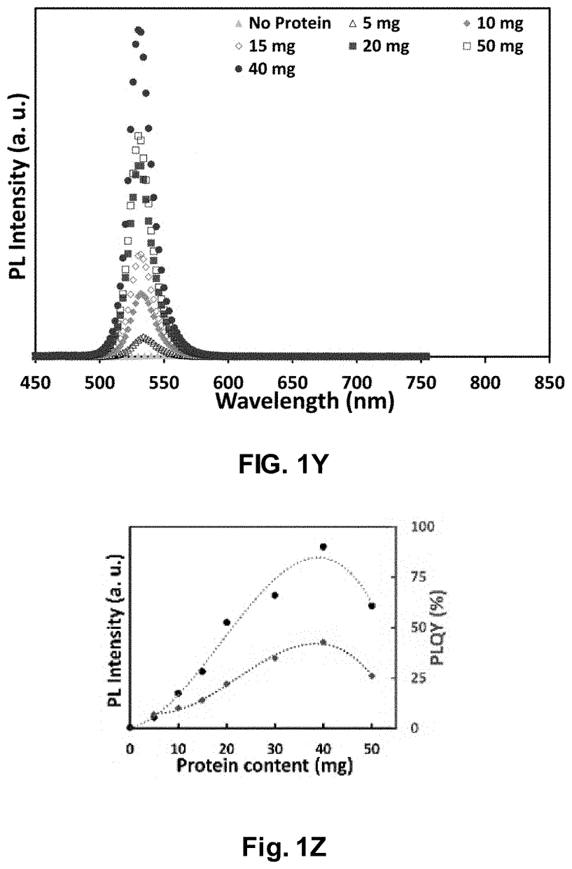

Results: Bovine serum albumin (BSA) was first used as model protein and optimized for the synthesis of BSA-stabilized HPNCs (BSA-HPNCs), in water under acidic conditions (FIG. 1A). The XRD patterns of as-synthesized HPs and BSA-HPNCs correspond to the cubic phase (ICDD #01-084-9476) of MAPbBr₃ (FIG. 1B). The main diffraction peaks are assigned to the corresponding lattice planes and the data confirms that the sample is pure and single phase. The strong XRD peaks generally imply high crystallinity of the sample and broader peaks in comparison with no protein added sample (Pure-HPs) mean crystals are in nanometer range. Moreover, a close inspection of the XRD patterns demonstrates that stronger diffractions at (200) and (210) lattice planes for the BSA-HPNCs compared with the Pure-HPs as well as reference pattern ((100) peak is the strongest). Without wishing to be bound by theory, this may be due to a preferred orientation during the growth of HPNCs in aqueous environment and in interaction with the protein.

PL spectra represent the characteristic green emission (≈531 nm) of colloidal BSA-HPNCs dispersion, which is blueshifted by ca. 30 nm compared to Pure-HPs (FIGS. 1C and 1E)). Also, BSA-HPNCs sample possesses an optical band gap of 2.31 eV calculated from the Tauc (FIG. 1D) plot corresponding to the direct band gap in MAPbBr₃. The calculated band gap of BSA-HPNCs is slightly higher than that of the Pure-HPs (FIGS. 1F-1G) and MAPbBr₃ bulk perovskite reported in literature, due to the quantum confinement effect. Photographs of the resultant BSA-HPNCs under room light and UV light (with glossy green emission) are also presented in (FIG. 1C). The FWHM of BSA-HPNCs and Pure-HPs are about 20 and 27 nm respectively, which is reasonably narrow in BSA-HPNCs case. Furthermore, the fast, slow, and average components of carrier lifetime are obtained to be 13.54, 58.33 and 26.15 ns respectively for BSA-HPNCs (FIG. 1H), which is slightly longer than the reported PL lifetimes for MAPbBr₃ nanocrystals. The slower components of the decay function corresponds to the radiative recombination of free charge carriers, whilst faster components are related to the nonradiative recombination of charge carriers.

TEM images illustrate BSA-HPNCs (FIGS. 1I and 1J) with the majority of HPNCs being less than 15 nm in size (with an average size of 7.2±2 nm as per the distribution shown in FIG. 1K) and having a spherical morphology. On the other hand, the sample synthesized with no protein (Pure-HPNCs) possesses very large particle size (>5 μm) with cubic morphology (FIGS. 1L-1M). The presence of both bright dots and rings simultaneously in the electron diffraction (SAED) patterns confirm high crystallinity and the polycrystalline nature of the synthesized HNPC. Also, lattice fringes corroborate the formation of crystalline materials with a d-spacing of 0.30 nm, corresponding to the (200) crystal facet of the cubic MAPbBr₃, in harmony with XRD result. However, some colloidal particles tend to agglomerate and form large clusters in consequence of polar nature of proteins and hydrogen bond formation, as depicted in FIGS. 1N-1O. Without wishing to be bound by theory, the faded shade (amorphous materials) surrounding some HPNCs is believed to be a network of BSA proteins. The elemental chemical composition of BSA-HPNCs by EDX reveals that N, O, Pb, and Br are present, while HPNCs have a halide-rich surface (FIG. 1P). In congruence with TEM results, the obtained crystal size from the SAXS results show that the majority of HPNCs have diameters below 10 nm (FIG. 1Q).

A TGA analysis was performed to evaluate the thermal decomposition of MAPbBr₃ particles synthesized with and without BSA, and compared with free BSA, to corroborate the formation of BSA-HPNCs composite (FIGS. 1R, and 1S). First, the physisorbed trace water evaporation below 150° C. caused a weight loss of ˜5.5% and 8.5% for BSA-HPNCs and pure BSA respectively, while this loss was negligible for HP particles synthesized without BSA. This was an indication that the BSA in BSA-HPNC composites remained incorporated with the HPNCs after isopropyl alcohol (IPA) washing and drying preparation steps. Second, the BSA-HNPCs showed a weight loss of 40% at about 300° C. vs. 25% of the pure-HPs corresponding to the loss of MABr. (FIGS. 1T and 1U). The higher MABr content of both pure-HPs and BSA-HPNCs vs. the theoretical 16.3% content in MAPbBr3 suggests the richer ionic surface of the synthesized particles, which is consistent with EDS results and those reported in the literature. The halide anion and CH₃NH₃⁺ cation-rich surface on the HPNCs are critical to maintain a necessary ionic balance and subsequently results in enhanced stability of the HNPCs and BSA-HNPCs in water. Third, MAPbBr₃ particles are thermally stable up to 250° C., above which they rapidly decompose due to the loss of organic material (MABr). Subsequently, there was a broad weight loss because of decomposition of remaining PbBr₂. Here, the MABr release step coincides with the BSA decomposition above 200° C., which has a broad mass loss with a maximum at about 315° C. In addition, the thermal decomposition of the polypeptide chain in BSA generates a small shoulder at 225° C. (FIG. 1V). Interestingly, the HPNCs capped with BSA exhibited a thermal decomposition trend corresponding to the average of both pure BSA and Pure-HPs. This was another confirmation of the integration of proteins and HPNCs.

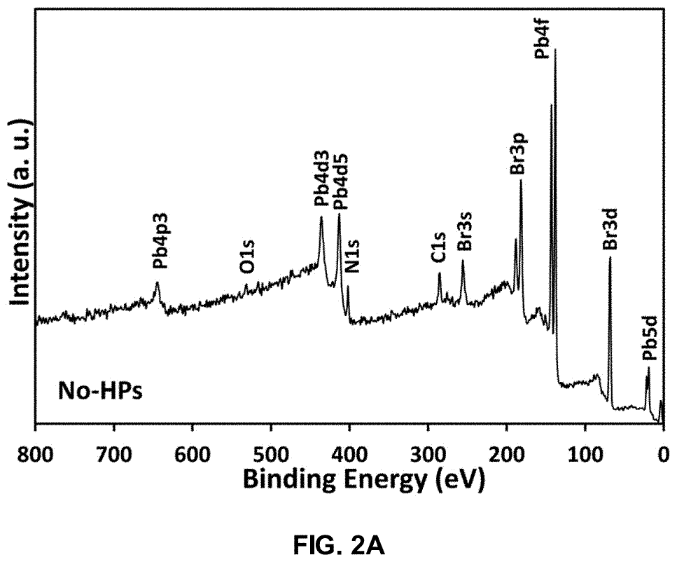

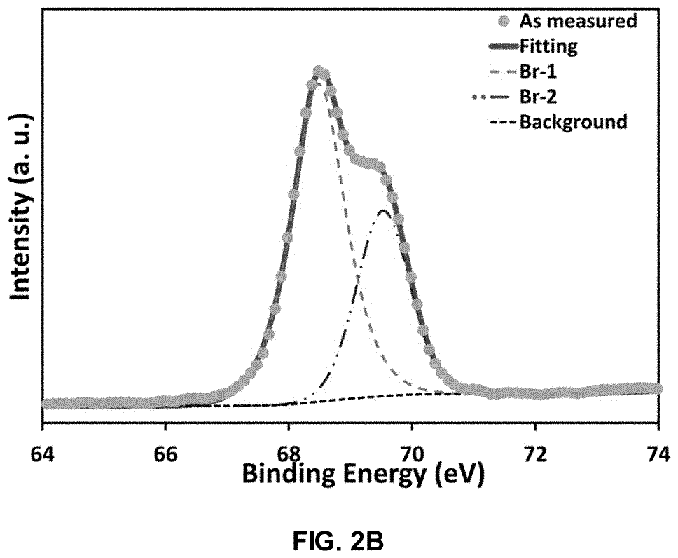

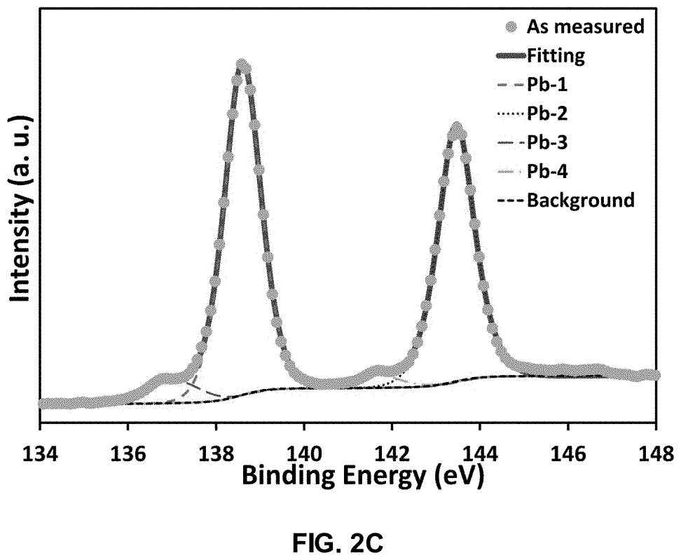

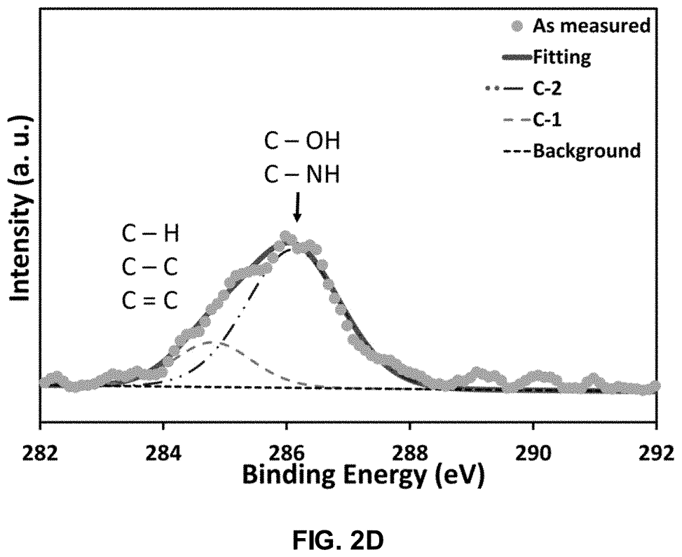

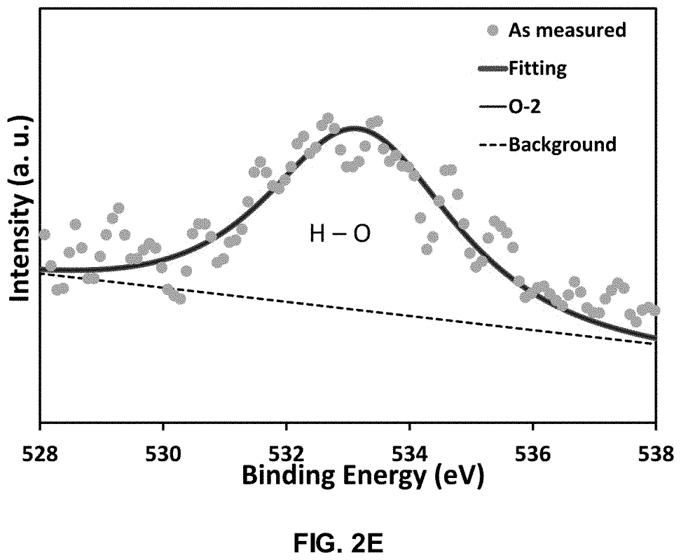

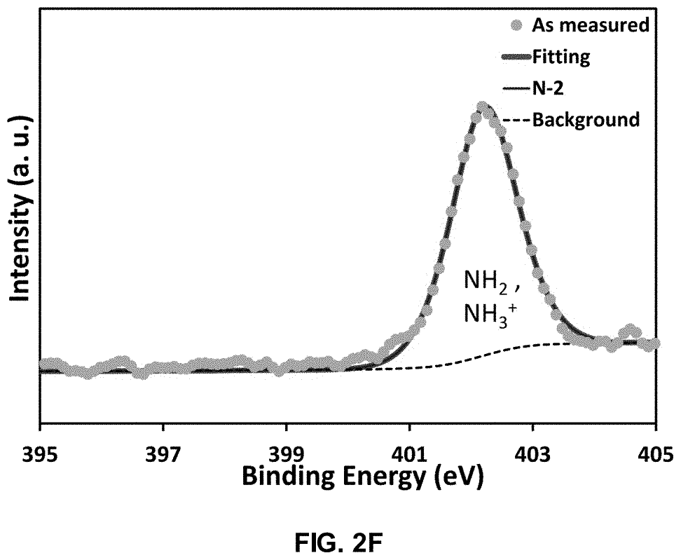

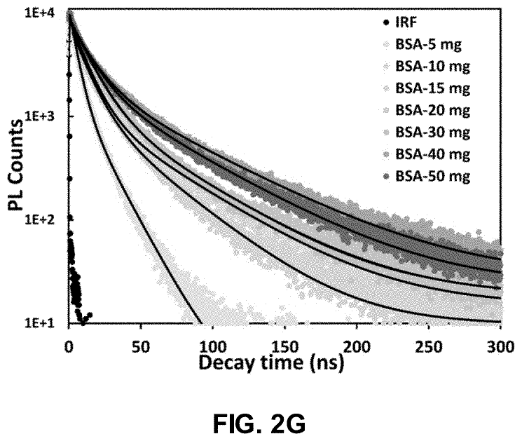

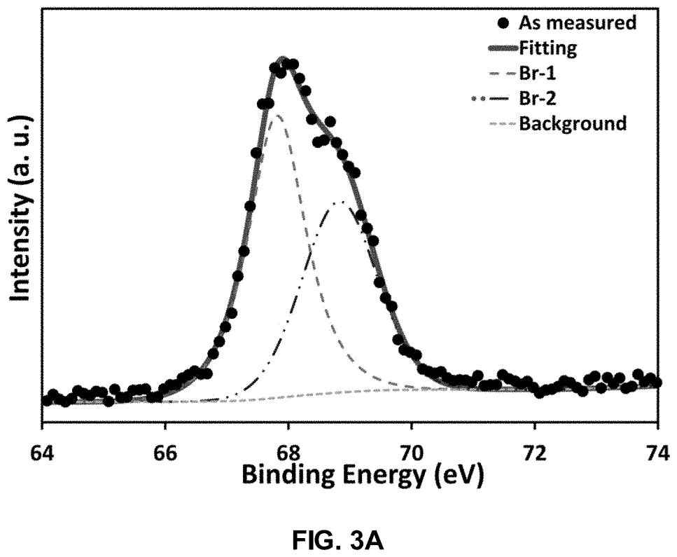

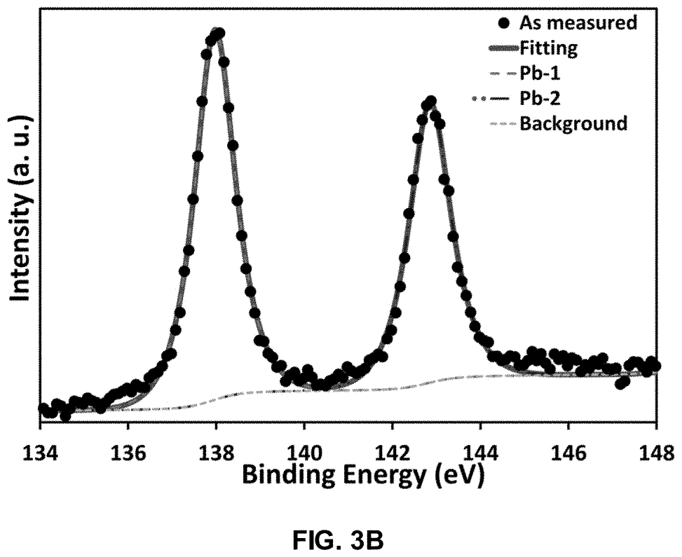

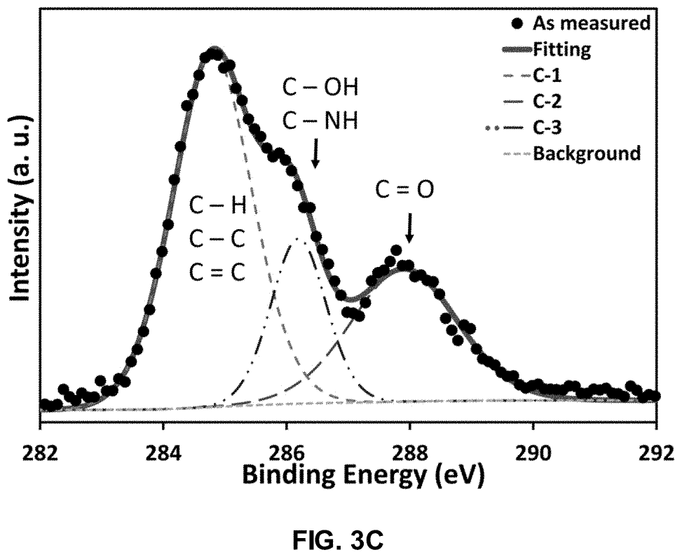

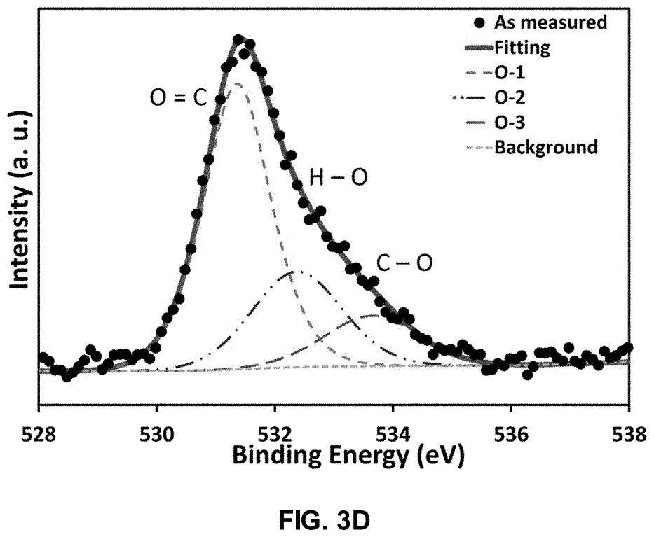

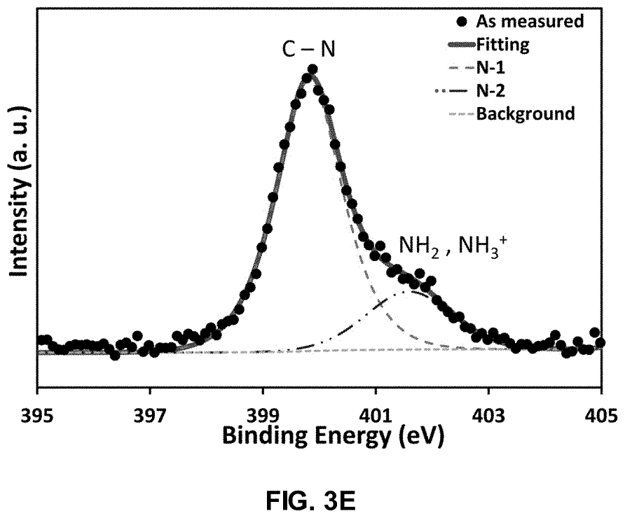

The surface of the prepared CH₃NH₃PbBr₃ samples was investigated with XPS to provide a detailed analysis of the surface chemistry of Pure-HPs and BSA-HPNCs for comparison. The overview spectra revealed the presence of Pb, Br, O, N, and C on the surface of the particles, however, BSA anchoring on the surface of HPNCs introduces higher concentration of N atoms as well as more C and O atoms, and therefore the corresponding peak intensities were stronger than Pure-HPs (FIGS. 1W and 2A-2F). It was found that both samples (pure HP and BSA-HPNC) exhibited an atomic ratio of Br:Pb on the surface of 3.5-4, which implies a Br-rich surface for the composite particles, in accordance with TGA results. High resolution elemental scans provided further insight of elemental configurations (FIGS. 2A-2F and 3A-3E). The sharp Pb 4f peaks at 138 and 142.8 eV stood for Pb 4f 7/2 and 4f 5/2. The absence of low energy shoulder of the Pb 4f at ca. 141.5 and 147 eV (FIGS. 3A-3E) revealed that almost all Pb ions were consumed in the BSA-HPNCs product to form perovskite, whereas they existed on the naked surface of Pure-HPs (FIGS. 2A-2F). Besides, the Br 3d peak can be divided into two peaks (i.e. 67.9 and 68.9 eV) corresponding to Br 3d5/2 and Br 3d3/2 spin orbitals, due to the inner and surface Br ions, respectively. The differences in C, O, and N peaks of Pure-HPs and BSA-HPNCs revealed more complex surface chemistry of BSA-HPNCs due to the presence of proteins (FIGS. 2A-2F and 3A-3E). The high-resolution C-1 (C—C, C═C and C—H), C-2 (C—NH, C—OH) and C-3 (C—O) of BSA-HPNCs were detected at about 285, 286 and 288 ev, respectively, while only C-1 and C-2 bonds were present on the surface of Pure-HPs. Also, there was only one weak distinguishable oxygen peak from Pure-HPs surface, but the O-1 (C═O), O-2 (O—H) and O-3 (C—O) were all available on BSA-HPNCs surface. Intriguingly, the core level spectra of N 1s for BSA-HPNCs comprises two peaks at binding energies 400 and 401.7 eV, implying the two existing chemical environments of the N element. The peak at 400 eV was attributed to the presence of protein proving that proteins behave as capping agents, and the other peak at 401.7 eV originated from methylamine in CH₃NH₃PbBr₃ composition. However, only corresponding N bonds of methylamine molecule were available from Pure-HPs surrounding. Also, the N:C ratio can be used as an indication of protein accumulation on the surface. Here, the N:C ratio of about 0.25 (compared with 0.2 for free BSA) indicated the attachment of BSA on the HPNCs surface. On the surface of BSA-HPNCs, an amount of more than 14 at % nitrogen was monitored, while this amount was about 13 at % for free BSA.

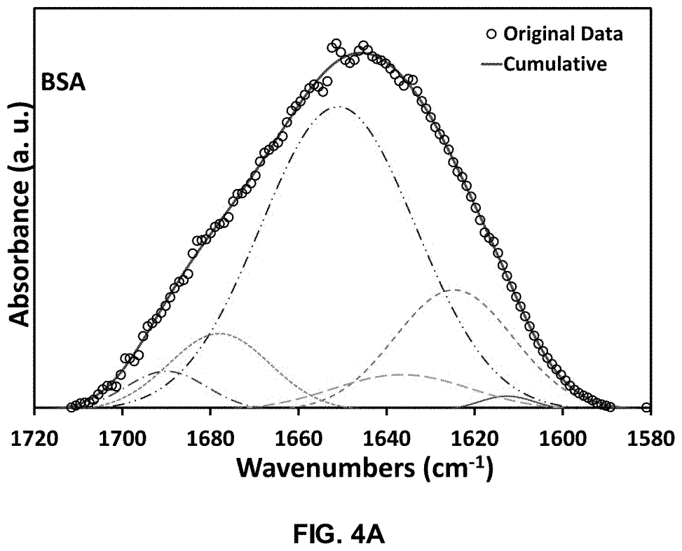

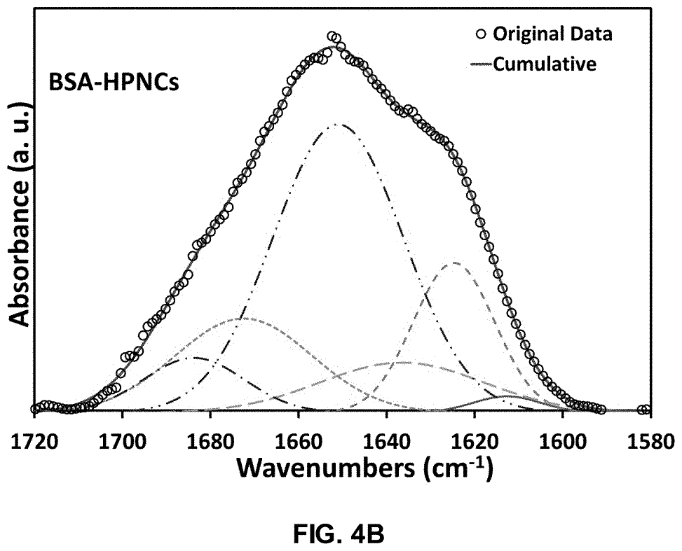

To probe the interactions of BSA with HPNCs as the result of the synthesis, FTIR spectra of free BSA were recorded, bare MAPbBr₃, and BSA-HPNCs. As displayed in FIG. 1X, the broad peak of free BSA at 3300 cm⁻¹ is corresponded to the O—H stretch of the phenol group. This peak also occurred for BSA-HPNCs but was not detectable in bare MAPbBr₃ sample, indicative of the interaction of the phenol group of tyrosine residue with HPNCs. The N—H stretch peak at about 3000 cm⁻¹ (of the primary amine) and two C—H₂ vibrational features at lower wavenumbers of pure BSA existed in BSA-HPNCs sample as well, but they did not appear in bare MAPbBr₃, suggesting that the amino groups of lysine residues and consequently BSA were contiguous on the HPNCs. However, both free HPs and BSA-HPNCs consisted of CH₃—NH₃⁺ rock and C—N stretch peaks at 915 and 970 cm⁻¹ respectively, while they did not appear in the free BSA spectra, thus BSA and HPNCs were well mixed and combined. More conspicuously, the protein amide I band at about 1650 cm⁻¹ (mainly C═O stretch of the carboxyl group) and amide II band at about 1535 cm⁻¹ (C—N stretching mode and N—H bending mode of the peptide backbone) were clearly visible for both pure BSA and BSA-HPNCs, but not for Pure-HPs. This was also a strong evidence of the coalescence among BSA and HPNCs. In order to evaluate possible changes in the secondary structure of BSA in BSA-HPNCs, the amide I peak was deconvoluted with second derivative resolution enhancement and curve-fitting procedures (FIGS. 4A and 4B). The quantitative analysis is summarized in Table 1. A clear BSA structural change in the amide I region can be easily observed following adsorption onto HPNCs surface. In free BSA, about 60.3% α-helix (1650 cm⁻¹), 19.3% parallel β-sheet (1625 and 1613 cm⁻¹), 10% turns (1675 cm⁻¹), 4% antiparallel β-sheet (1690 cm⁻¹) and 6.4% random coil (1637 cm⁻¹) were measured (Table 1), in accordance with the conformation of BSA in the literature. Upon interaction with HPNCs, a major decrease of α-helix content, from 60.3% (free BSA) to 48.6% (BSA-HPNCs) was observed, with a rise in the turn structures, from 10% to 16.6% (BSA-HPNCs) (Table 1). These conformal changes could result from BSA being exposed to a very acidic environment with high ionic strength during HPNC synthesis, which could contribute to partial protein unfolding. However, the overall protein structure was maintained, indicative of sustainable and well composition of the HPNCs surface with BSA.

TABLE 1
Secondary structure analysis of the pure BSA and as-synthesized
BSA-HPNCs obtained from FTIR spectra of amide I region.

| Amide I (cm⁻¹) components | BSA | BSA-HPNC | Ref. |
|---|---|---|---|
| α-helix | 60.28 | 48.58 | Bi et al. |
| β-sheet (parallel) | 19.32 | 17.16 | Shamsi et al. |
| random coil | 6.35 | 10.57 | Geng et al. |
| Turn | 9.99 | 16.58 | Hamill et al. |
| β-sheet (antiparallel) | 4.06 | 7.11 | Jing et al. |

It was then sought to determine the effect of protein content on the PL emission intensity of the BSA-HPNCs (FIGS. 1Y-1Z). As BSA is added (up to 600 nmol), the PL emission of MAPbBr₃ HPNCs was significantly enhanced, which can be attributed to the protection of the HPNC's surface by proteins. Sharma et al. comparably showed that concentration of amino acids have vital role in mediating MAPbBr₃ nanocrystals. Both PL lifetime and PLQY of the BSA-capped NCs increase as a function of BSA concentration as illustrated in FIGS. 1Y-1Z and 2G, and also summarized in Table 2. At higher capping agent concentration (750 nmol), smaller HPNCs might form and steric hindrance among the proteins may cause inferior passivation and difficult diffusion of ions inside the protein network, which means a higher density of surface vacancies and poorer optical properties, resulting in a slightly lower PL intensity. Therefore, the higher concentrations of protein leads to the superior capping and protection of HPNCs, the more binding sites to promote interactions, the smaller nanocrystals, and the better surface defects passivation.

TABLE 2
Summary of optical properties of HPNCs synthesized with different
amounts of BSA. Lifetime parameters obtained from a fitted bi-
exponential function from the time resolved PL spectra

| BSA | PL | | | | |
|---|---|---|---|---|---|
| content | emission | | | | |
| (mg) | [counts] | τ1[ns] | τ2[ns] | τavg[ns] | PLQY [%] |
| 5 | 27370 | 4.83 | 16.7 | 6.85 | 7 ± 2 |
| 10 | 87050 | 10.23 | 47.96 | 15.4 | 10 ± 2 |
| 15 | 141040 | 10.31 | 38.42 | 15.85 | 14 ± 3 |
| 20 | 263190 | 12.16 | 47.5 | 18.1 | 22 ± 5 |
| 30 | 330150 | 12.88 | 49.4 | 19.14 | 35 ± 5 |
| 40 | 450340 | 13.54 | 58.33 | 26.15 | 43 ± 4 |
| 50 | 304290 | 12.88 | 53.42 | 23.53 | 26 ± 5 |

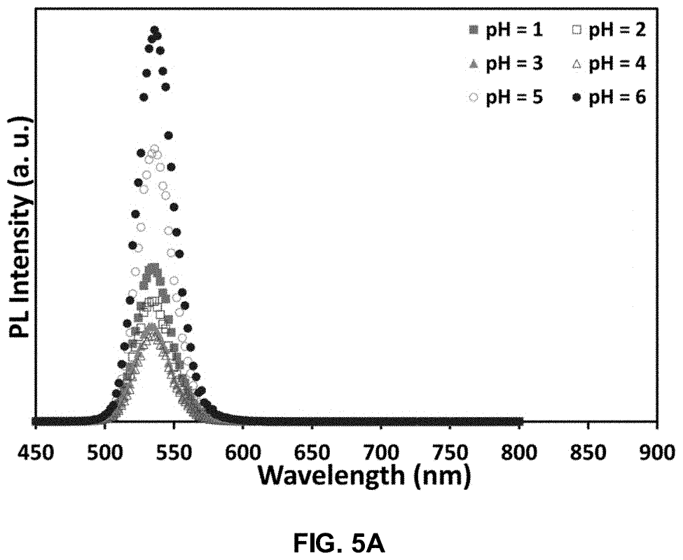

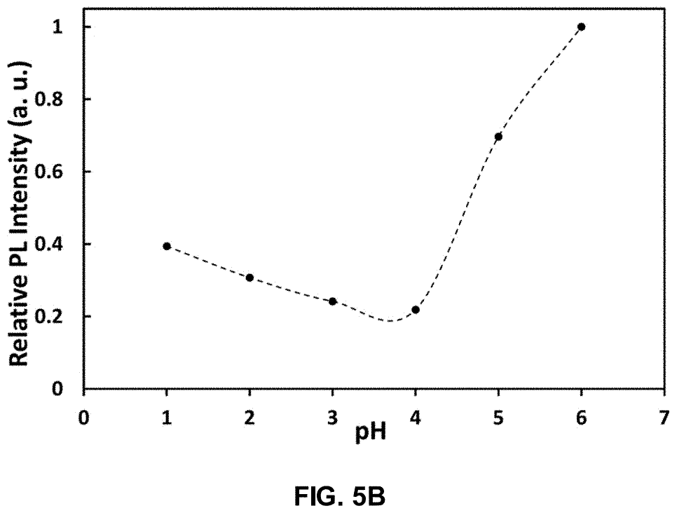

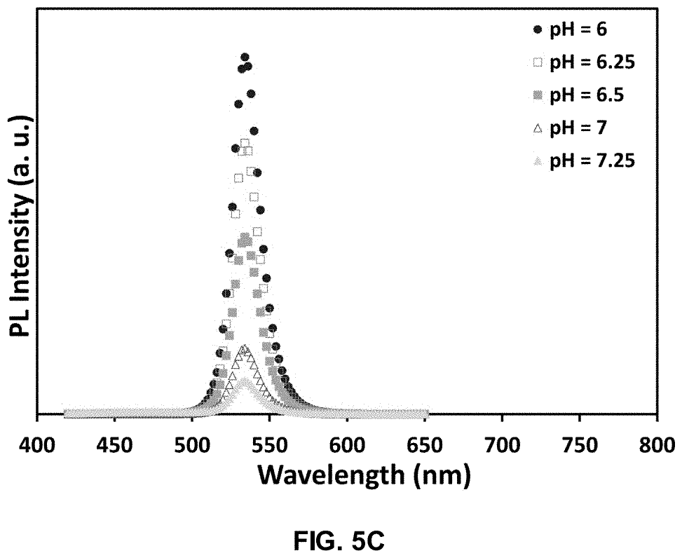

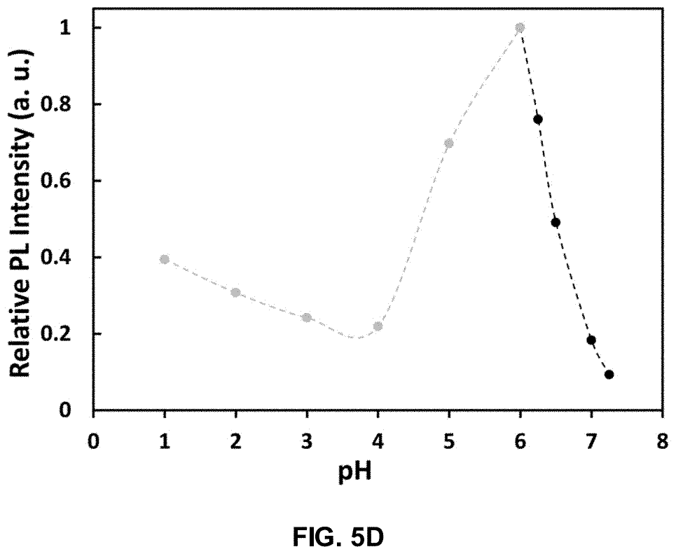

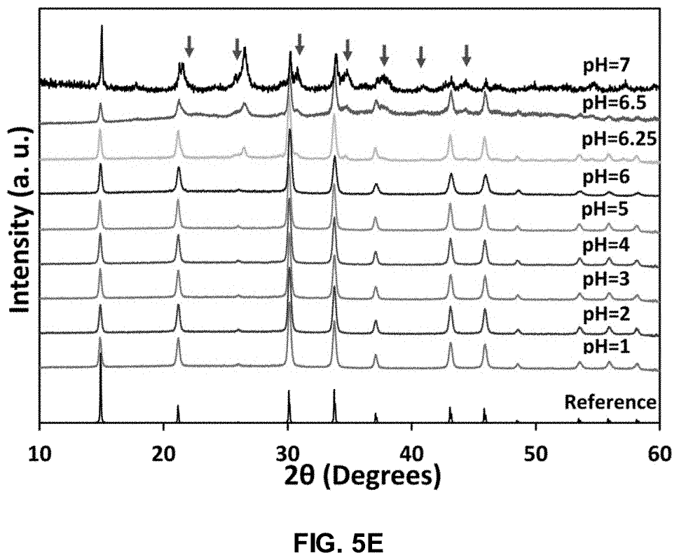

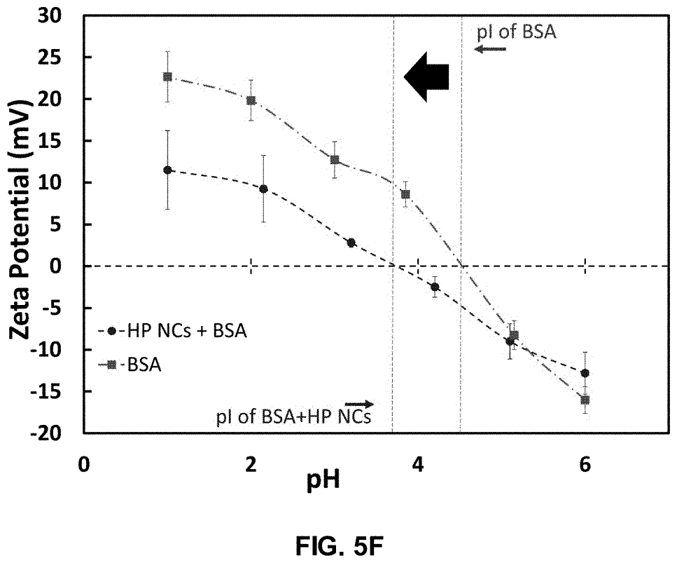

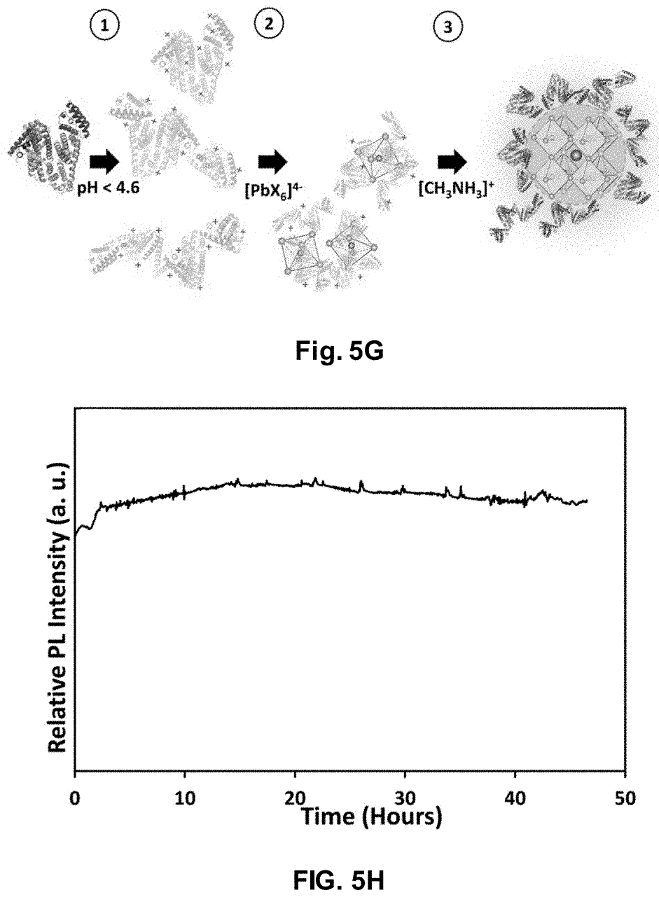

Next, the stability of BSA-HPNCs was studied. PL measurements of colloidal HPNCs revealed a strong dependency on pH. Interestingly, while HPNCs are synthesized under acidic conditions (pH<1), it was observed that they remain luminescent when increasing the pH to ˜7 (FIGS. 5A, 5B, 5C and 5D). Intriguingly, the PL intensity did not vary linearly as the pH increased. The emission first decreased as pH increases and reached a minimum at around pH=4, while it abruptly increased above pH=4 and shows the highest intensity at around pH=6. Above pH 6 the BSA-HPNCs tend to decompose, aggregate and precipitate out of the solution, while the colloidal solution starts to become whiter (indicative of HPNCs degradation and PbBr₂/Pb(OH)₂ formation). To investigate the structural stability of BSA-HPNCs at different pHs, the XRD patterns of samples incubated at different pHs were studied (FIG. 5E). The diffraction patterns showed the exclusive presence of the cubic phase of the MAPbBr₃ perovskite at all pHs≤6. Above pH 6, additional peaks appeared at 2θ of about 25.8, 30.7, 34.9, 37.7, 44.4°, and etc. This was an indication that degradation of HPNCs occurred, and that further pH rise above 6 is detrimental to the HPNCs. Therefore, the PL intensity dropped again at pHs above 6 (FIGS. 5C and 5D) which means HPNCs were not stable anymore and tended to degrade progressively towards pH≈7, though, there were still HP's emission peaks present even at slightly higher than neutral pH (FIGS. 5C and 5D).

pH plays a determinative role in HPNCs formation. With the intention of comprehension of the protein adsorption at the HPNCs interface at the molecular level, zeta potential, as an indication of electrostatic repulsion between colloidal particles, can greatly assist. Accordingly, the impact of pH on the zeta potential of pure BSA and BSA HPNCs was explored (FIG. 5F). BSA-HPNCs demonstrated a similar pH-dependent zeta potential trend as pure BSA, but the pI was shifted towards more acidic region (pH=3.8), corroborating the idea that BSA proteins were adsorbed on the surface of HPNCs. In more details, the zeta potential of BSA molecules decreased from 22.6 mV to −16 mV with increasing pH from 1 to 6, with an isoelectric point (pI) at pH˜4.6, in accordance with literature. On the other hand, the positively charged BSA-HPNCs were colloidally stabilized by strong electrostatic charges at pH<3, while they became unstable and had a tendency to coagulate at pH 3-4. By further increasing the pH, BSA-HPNCs experienced a surface charge change into negative values, analogous to pure BSA. Hence, the strong positive and negative surface charges before and after pH=3-4 rage respectively, lead to stabilized colloidal BSA-HPNCs. Taken together, the zeta potential, elemental characterizations and FTIR results, allowed to conclude that BSA-HPNCs have a strongly charged surface together with rich surface in methylammonium bromide. Considering the presence of a charge balance in the acidic aqueous solution, this surface chemistry is beneficial to maintain dispersibility and stability of the BSA-HPNCs in solution with enhanced PL emissions compared with MAPbBr₃ without BSA. At pH>6 a white precipitate slowly formed as a sign of decomposition, which was a mixture of CH₃NH₃PbBr₃, PbBr₂, and Pb(OH)₂, according to XRD results (FIG. 5F).

The relationship between pH, PL intensity and zeta potential for BSA-HPNCs differed from that reported previously for the amino acid (phenylalanine (PLLA)) assisted synthesis of HPNCs, and thus can provide a new method for improving stability of HPNCs in aqueous environments. Geng et al. synthesized PLLA-HPNCs directly in aqueous solution in acidic range (pH=0-6) using a lead halide complex and methylamine. They proposed that firstly halogen acid, which is necessary to dissolve lead halide in water, creates [PbBr₆]⁴⁻ complex from the reaction with PbBr₂. Secondly, luminescent PLLA-HPNCs suspension can form via the reaction between methylamine and lead halide complexes. These dynamic reactions prevent the water-induced decomposition of PLLA-HPNCs by maintaining the proper ionic balance on the halide-rich surface of PLLA-HPNCs through providing [PbBr₆]⁴⁻ complexes and H⁺ (H₃O⁺) and CH₃NH₃⁺ cations. Although, pH had a crucial impact on both stabilization and properties of the PLLA-HPNCs, there was no pI value. The surface of colloidal formed particles was positively charged at pH<6, and PL intensity showed a maximum between pH 0 and 3, and declined above pH=3, in contrast to BSA-HPNCs. The PLLA-HPNCs fully decomposed into white precipitates at pH 7, while BSA-HPNCs were still weakly luminescent even at pHs slightly higher than 7 (FIGS. 5C and 5D) due to superior capping ability of proteins. In addition, the PLQY and stability of the BSA-HPNCs are greater than values reported for PLLA-HPNCs.

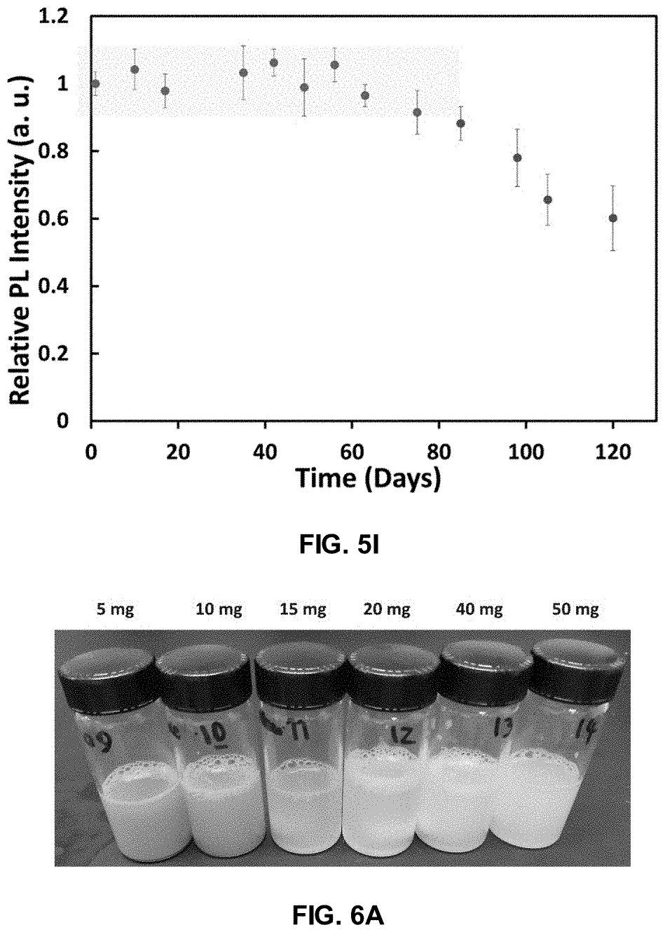

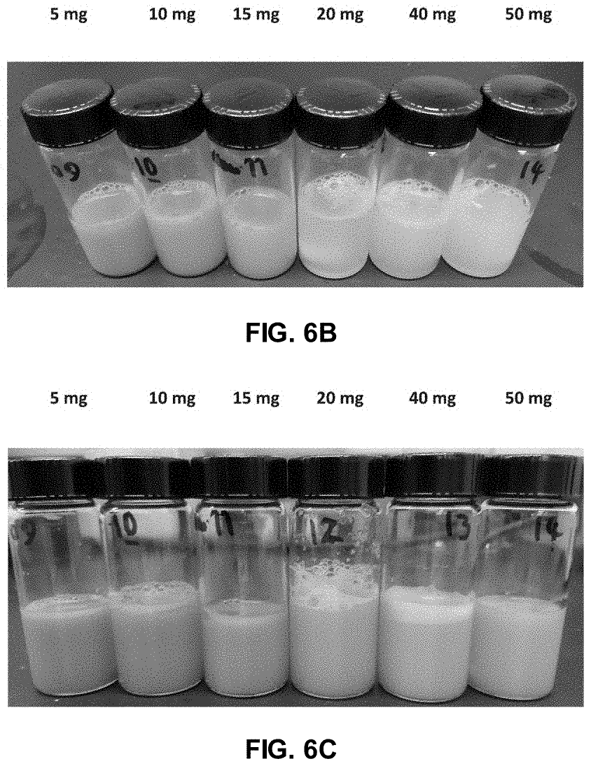

Therefore, a model for the BSA-HPNCs interaction in water was proposed and outlined in FIG. 5G. Both acidic and basic functional groups are available in BSA, and the charge on the protein necessarily relies on the pH of the surrounding solution. Protonation of the acidic (R—COO⁻→R—COOH) and basic (R—NH₂→R—NH₃⁺) groups occurs at pHs lower than the pI, which causes a net positive surface charge. On the contrary, deprotonation takes place at pHs higher than the pI and results in a net negative surface charge. Moreover, structural transitions of BSA are pH-dependent: N (normal), F (fast), and E (expanded) conformations at pH 4.5-7.0, 4, and <3, respectively. The N and F forms of BSA have globular and partially opened with a considerable loss in helical content conformations, respectively, while additional expansion with a loss of intradomain helices results in the E state of BSA, in perfect harmony with FTIR amide I peak deconvolution results (Table 1). α-helices are spread to a larger degree and transform into β-sheets and turns (analyzed with FTIR (Table 1)) upon the pH of the solution reduces. This supports creation of a conformation that is suitable for the growth of NCs and provides easy access to functional groups for binding. Therefore, PbBr₄⁻ ions attach to the cationic BSA templates, which is formed with the help of acidic environment. Additionally, BSA expanded conformation benefits in superior passivation of HPNCs, as schematically illustrated in FIG. 5G. In fact, PbBr₄ complexes are formed at acidic conditions due to the hydrolysis of lead bromide in the presence of HBr. BSA, with an isoelectric point of 4.6, possessed positive surface charges in the reaction solution, and thus, PbBr₄⁻ complexes had strong tendency to electrostatically attach to the structurally expanded BSA. Subsequently, the added CH₃NH₃⁺ diffused within BSA structure and reacted with lead bromide complexes attached to the BSA to form HPNCs. In order to better understand the HPNCs formation kinetic, methylammonium (MA) solution was added at a very slow rate into the reaction vials with different concentration of BSA (5 mg, 10 mg, 15 mg, 20 mg, 40 mg and 50 mg) and incubated for 4 days. As shown in FIGS. 6A-6C, yellow-orange colloidal HPNCs formed faster in solutions with less BSA. The color of the samples with higher concentration of BSA has turned into yellow-orange very slowly. This suggests that there is a barrier against the formation of HPNCs and MA cations required to diffuse within that fence before they can reach and react with PbX₆⁴⁻ to form HPNCs. Thus, the kinetic of the formation reaction depends on the concentration of proteins in the current synthesis approach.

Astoundingly, the synthesized BSA-HPNCs solution demonstrates high photochemical stability upon exposure to continuous 405 nm wavelength. There is a slight increase of PL intensity during the initial few hours of irradiation—probably until a thermal equilibrium with the environment—and then reaches close-to-constant values up to 48 hours (FIG. 5H). Furthermore, the sample exhibits long-term colloidal stability, with a PL intensity remaining approximately constant over several weeks when stored in a capped container under ambient conditions (FIG. 5I). After 4 months, the PL emission decreases to 60% of its original intensity of freshly synthesized sample. These photochemical and long-term stabilities are considerably higher than previously reported PLLA-HPNCs synthesized in water and stored under ambient conditions.

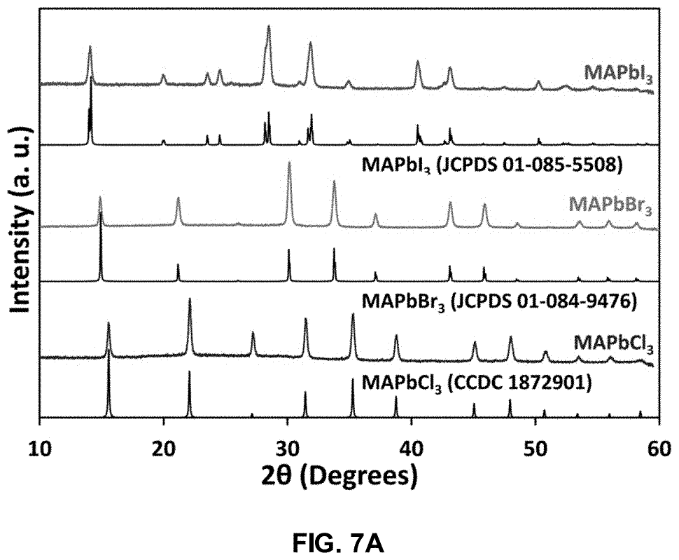

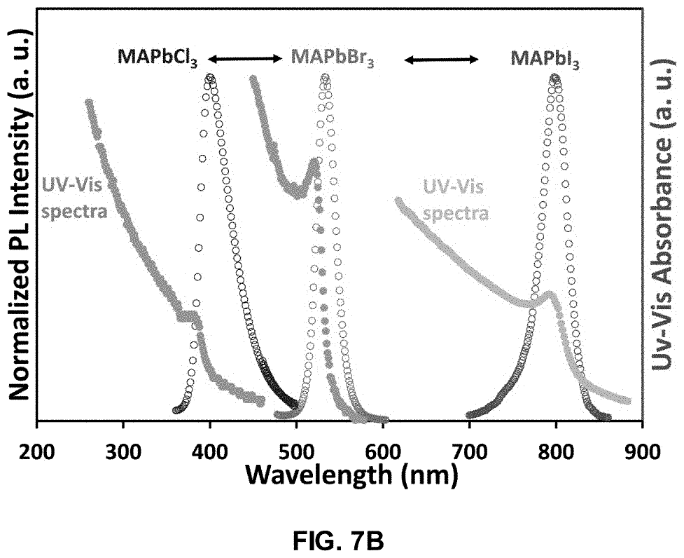

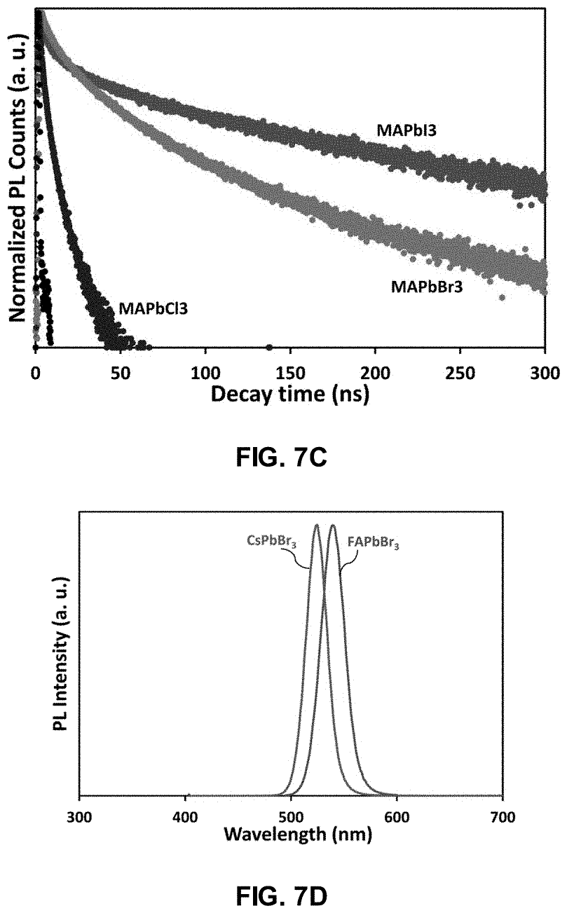

In order to demonstrate the versatility of the present method, different perovskite compositions were produced by using other halide ions. As shown in FIG. 7A, BSA-MAPbI₃ and -MAPbCl₃ along with BSA-MAPbBr₃ perovskites can be produced, and exhibit tetragonal and cubic crystal structures, respectively. All peaks were entirely matched with reference data with no additional MAX or PbX₂ phase peaks, clearly indicating that all samples were of high phase and composition purity. Similar to BSA-HPNCs, a set of preferred orientations can also be observed for BSA-MAPbI₃ and -MAPbCl₃ as an effect of protein molecules surrounding the HPNCs in aqueous media.

The UV-vis light absorption and PL spectra of BSA-HPNCs with different halide ions are obtained. As shown in FIG. 7B, the PL spectra of BSA-MAPbCl₃, BSA-MAPbBr₃ and BSA-MAPbI₃ HPNCs showed highest intensities at 400, 535 and 800 nm respectively, consistent with previously reported results for the BSA-CH₃NH₃PbX₃ materials. Although, BSA-MAPbBr₃ and BSA-MAPbI₃ HPNCs had relatively narrow FWHM of 20 and 32 nm respectively, BSA-MAPbCl₃ HPNCs had a FWHM of 40 nm, which was higher than that of formerly reported values (Table 3). Also, PL decays reveal PL lifetimes of the band-edge excitons in the range of 2.55-41.68 ns with slower decay for narrower-bandgap BSA-MAPbI₃ composition (FIG. 7C and Table 3). BSA-MAPbBr₃ exhibited longer τₐᵥₑ than BSA-MAPbCl₃, while it had lower τₐᵥₑ than BSA-MAPbI₃. This indicates lower recombination rate in BSA-MAPbI₃ HPNCs compared to the chloride and bromide types, which is in agreement with the formerly reported results. PLQY of different compositions (Table 3) indicated that BSA-MAPbBr₃ had the highest value of 43%, which decreased by substitution with Cl and I to 9 and 26%, respectively. In addition, the synthesis of different perovskites with substitutions for methylamine, e.g., Cs and FA (formamidinium (CH(NH₂)₂⁺)) were successively performed, thereby demonstrating the versatility of the present method approach (FIG. 7D).

TABLE 3
Summary of spectroscopic characterizations and lifetime decays
of different BSA-MAPbX₃ (X = Cl, Br and I) nanocrystals compositions
mediated by BSA. The lifetime parameters obtained from a fitted
biexponential function from the time resolved PL spectra.

| | | Band | | | | |
|---|---|---|---|---|---|---|
| | FWHM | Gap | | | | PLQY |
| Composition | (nm) | (eV) | T₁(ns) | T₂(ns) | T_{avg} (ns) | (%) |
| BSA-MAPbCl₃ | 40 | 3.12 | 1.93 | 7.94 | 2.55 | 9 ± 4 |
| BSA-MAPbBr₃ | 20 | 2.31 | 13.54 | 58.33 | 26.15 | 43 ± 4 |
| BSA-MAPbI₃ | 32 | 1.52 | 8.96 | 104.23 | 41.68 | 26 ± 3 |

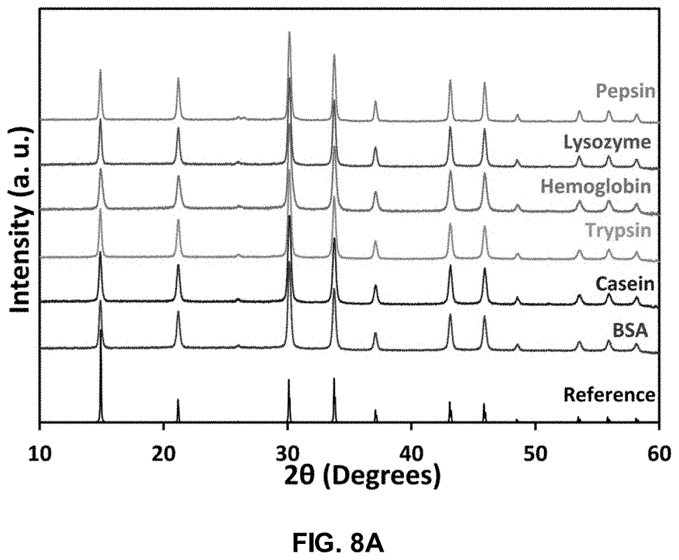

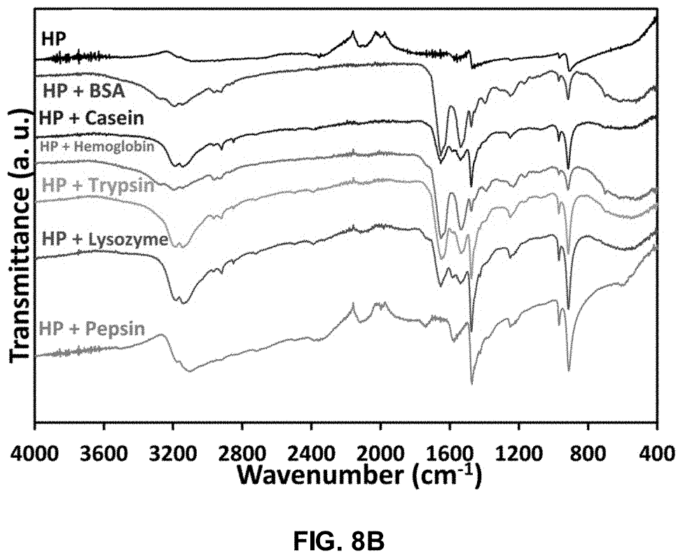

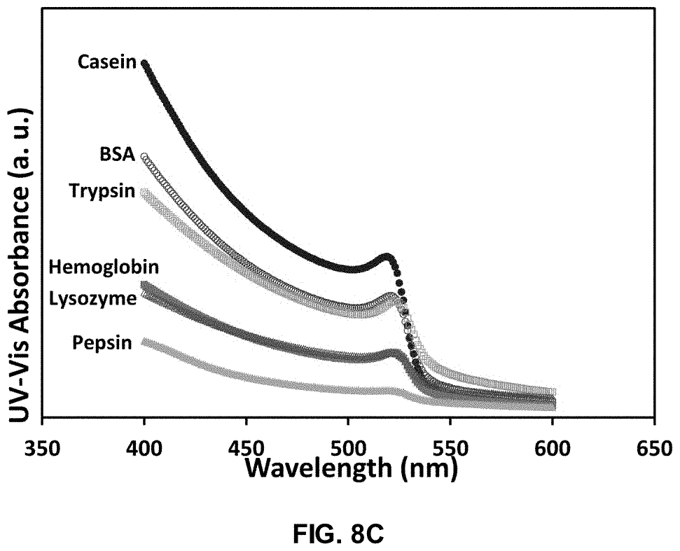

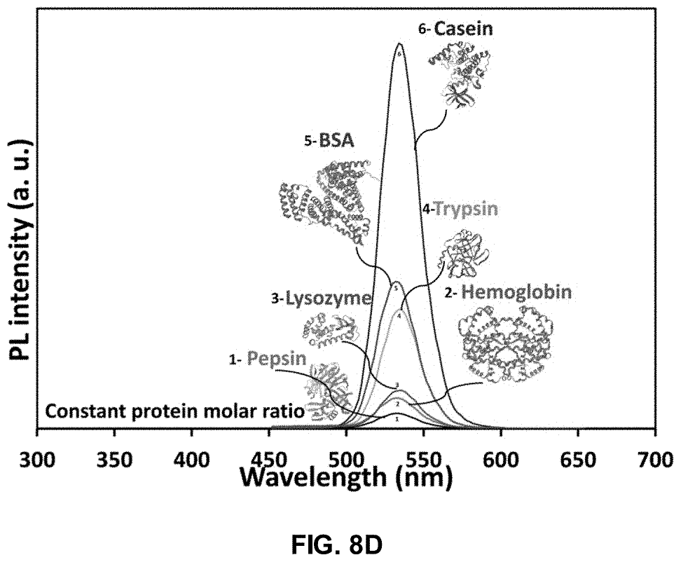

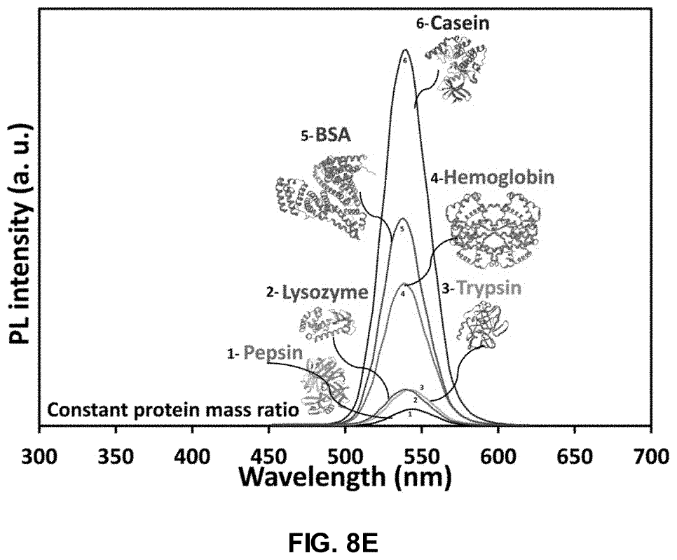

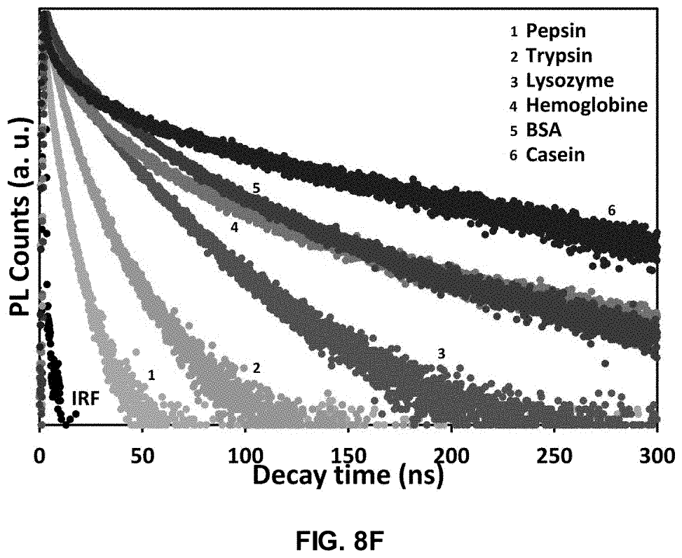

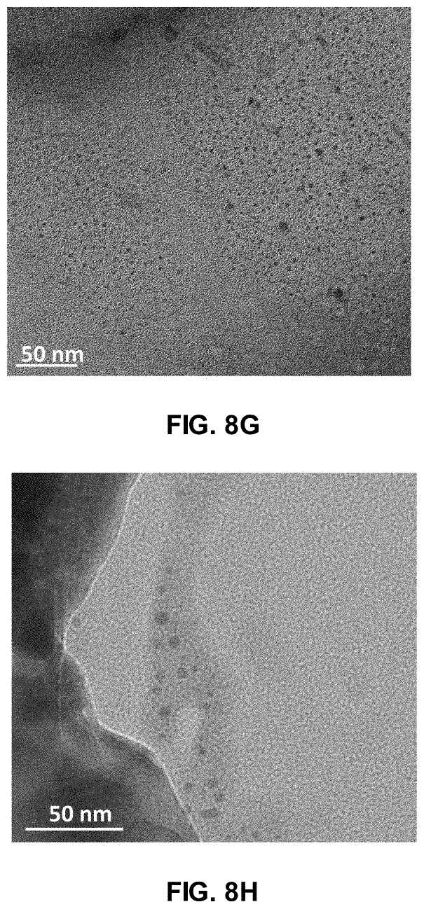

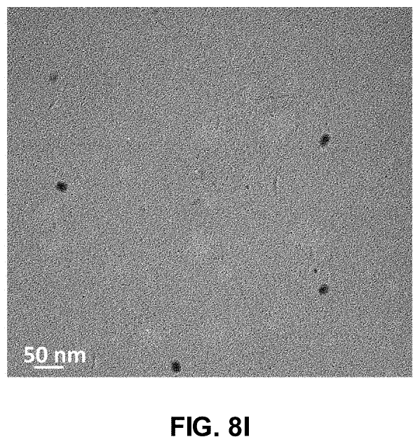

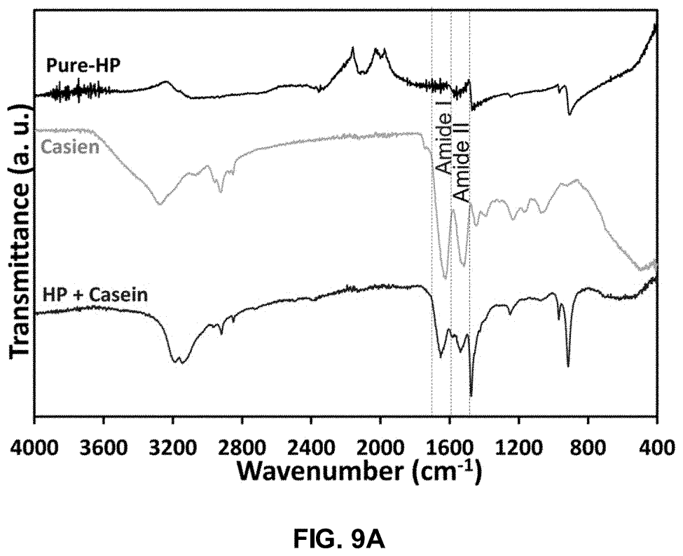

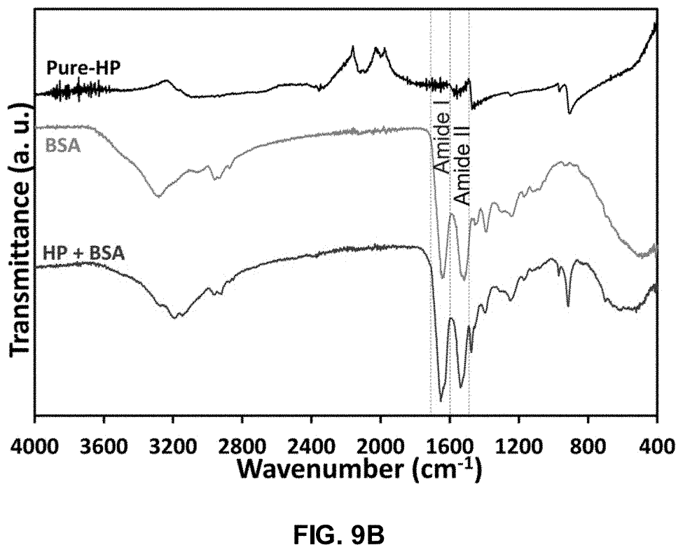

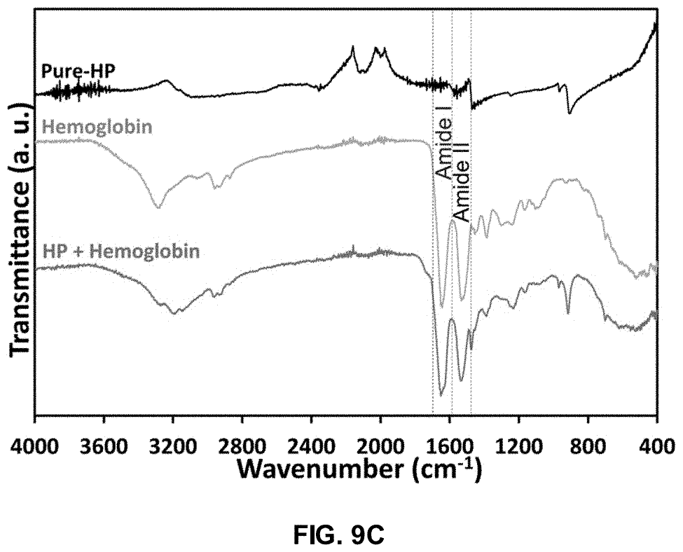

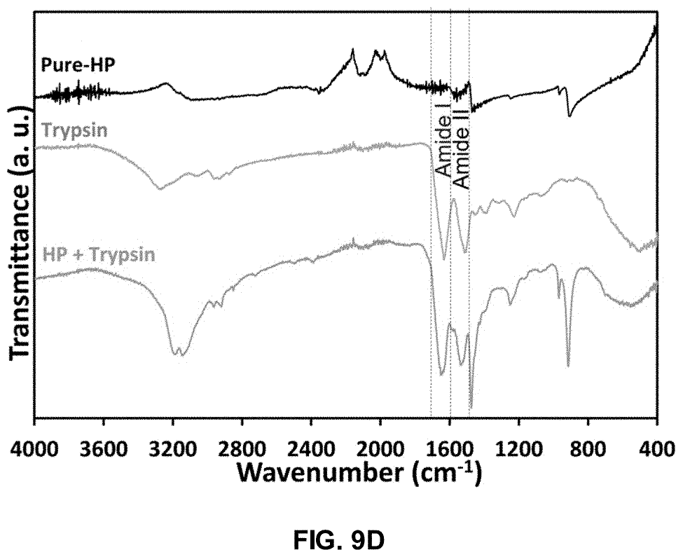

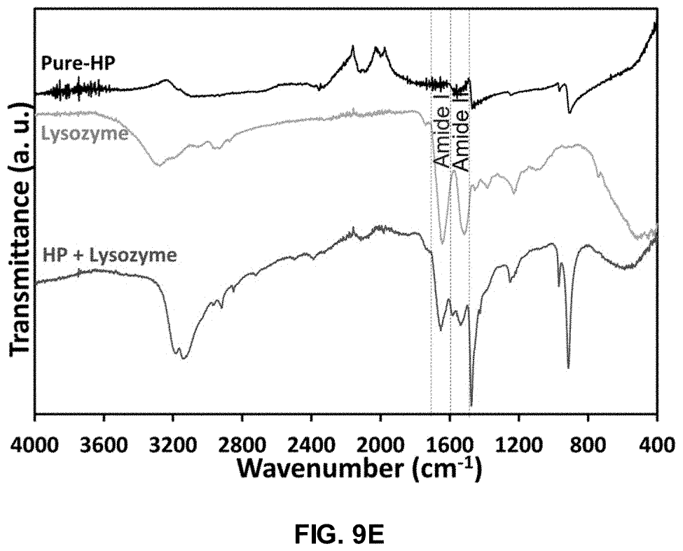

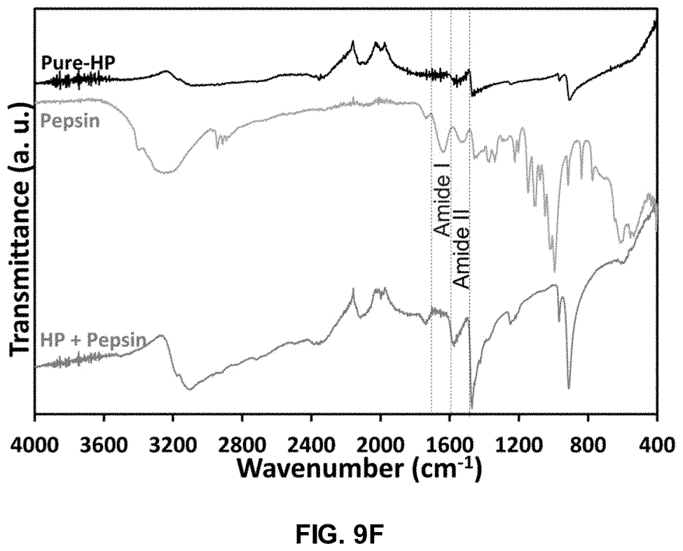

To explore whether the present approach could be generalized to other proteins and to explore the effects of protein biochemistry on HPNCs properties, BSA was replaced with a selection of proteins (casein, hemoglobin, lysozyme, trypsin, pepsin) with a wide range of molecular weights and isoelectric points. In FIG. 8A, XRD patterns of samples synthesized with different proteins are compared. The XRD patterns show that cubic MAPbBr₃ phase is dominant in all samples, regardless of the protein used as stabilizer. Further comparison of the XRD patterns reveal that there are negligible XRD peak shift among samples, which further confirms that proteins only act as capping agent on the surface of HPNCs. FTIR spectra of protein HPNCs are presented in FIG. 8B and FIGS. 9A-F. Just like BSA-HPNCs, the amide I and II regions were observed in all samples synthesized with different proteins, as a confirmation of the combinations of proteins and HPNC nanocomposites. However, the two amide I and II peaks were less obvious for pepsin-HP composite, which can be due to the weaker interaction between this protein and HPNCs, and a potential explanation for its weaker optical properties (Table 4 and FIGS. 9A-F).

TABLE 4
Summary of used proteins properties as well as optical characterizations
of HPNCs synthesized with different proteins. Lifetime parameters obtained
from a fitted bi-exponential function from the time resolved PL spectra.

| | | | | Band | | | | |
|---|---|---|---|---|---|---|---|---|
| | GRAVY* | MW | | Gap | | | | PLYQ |
| Protein | No. | (kDa) | pl | (eV) | T₁(ns) | T₂(ns) | T_{avg}(ns) | (%) |
| Casein | −0.481 | 24 | 4.3-4.6 | 2.32 | 7.85 | 95.66 | 34.49 | 44-56 |
| BSA | −0.380 | 67 | 4.5-4.7 | 2.31 | 13.54 | 58.33 | 26.15 | 37-48 |
| Hemoglobin | 0.022 | 64.5 | 6.8 | 2.31 | 12.18 | 65.01 | 26.07 | 15-25 |
| Lysozyme | −0.150 | 16 | 11.4 | 2.30 | 8.39 | 29.91 | 15.82 | 7-15 |
| Trypsin | −0.151 | 24 | 10.1 | 2.30 | 5.28 | 18.50 | 7.03 | <9 |
| Pepsin | −0.145 | 35 | <3.0** | 2.28 | 2.63 | 8.22 | 3.65 | <3 |

*GRAVY = Grand average of hydropathy value for protein sequences
**Often, very pure pepsin solutions showed no isoelectric point

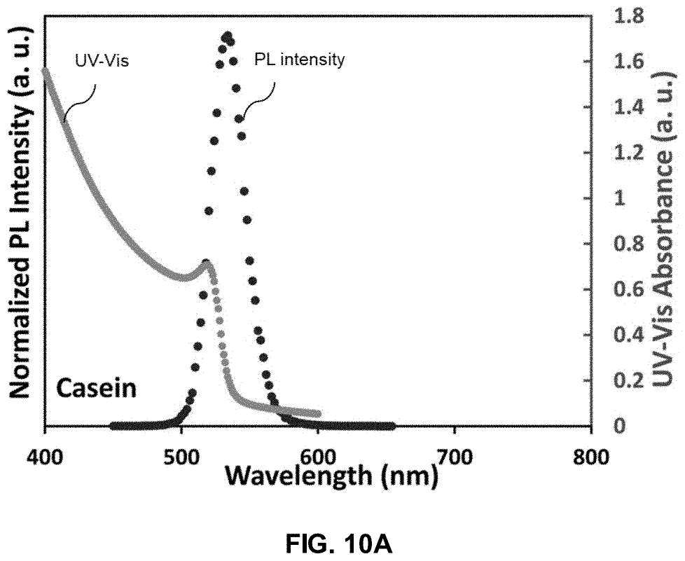

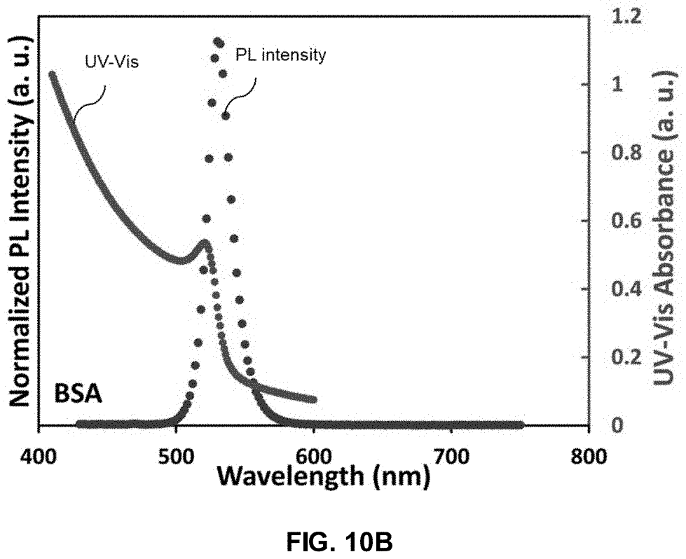

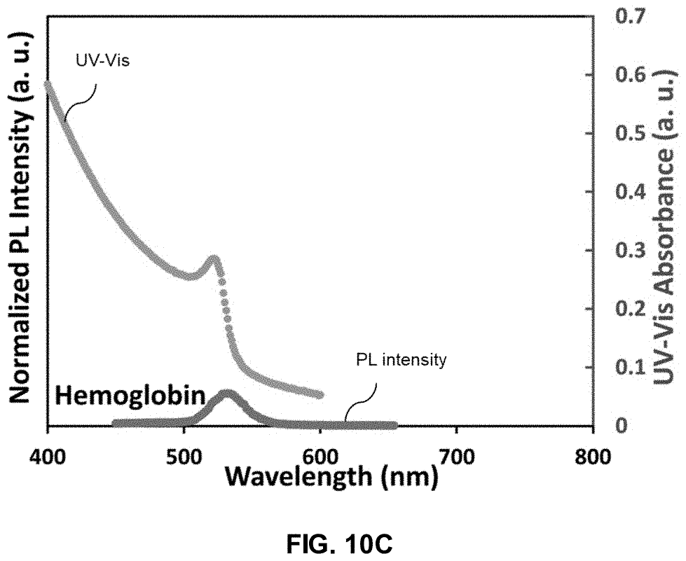

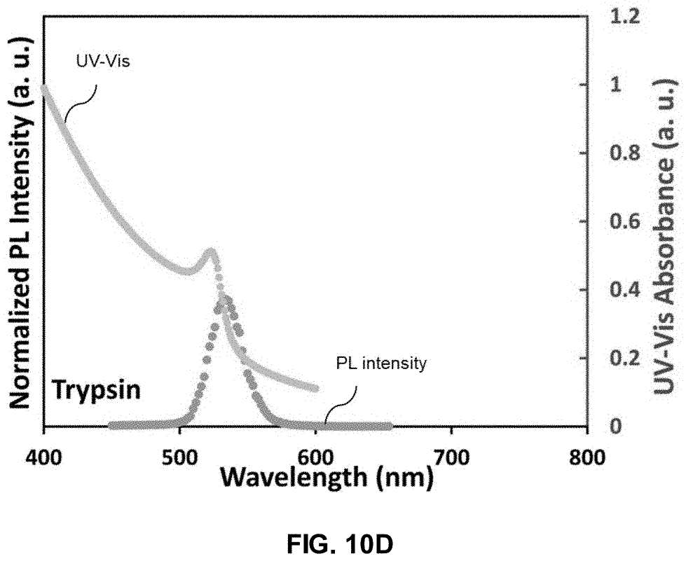

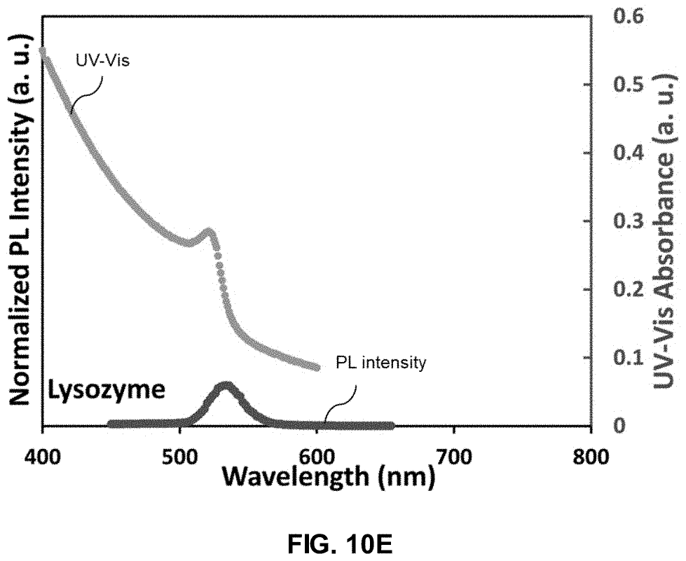

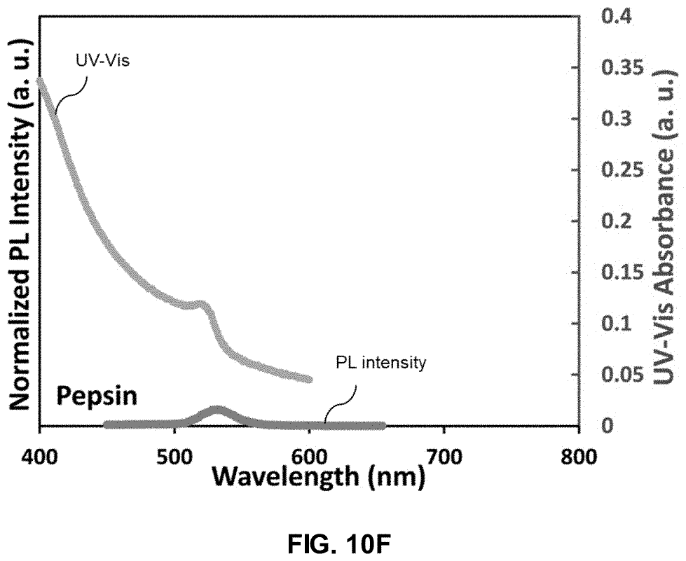

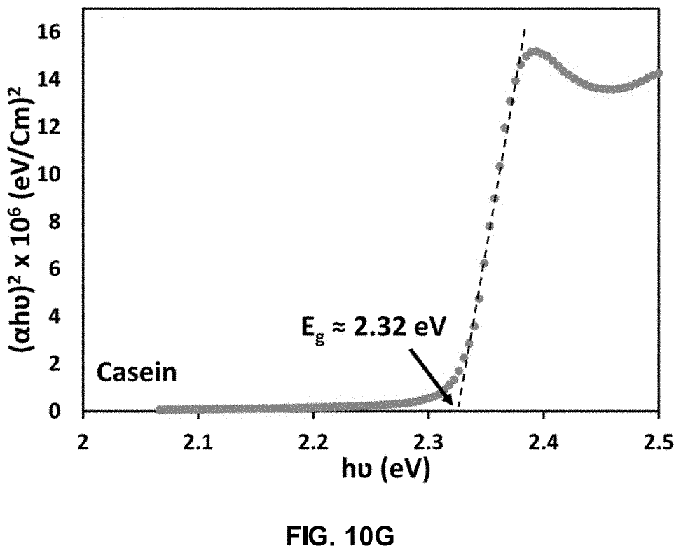

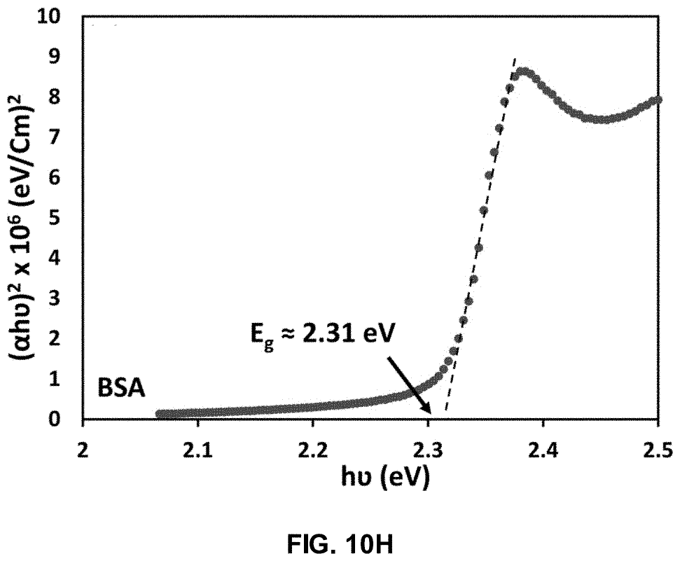

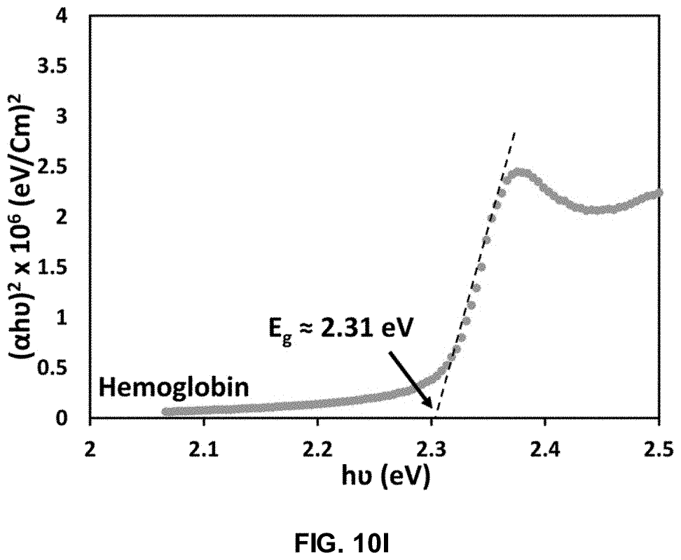

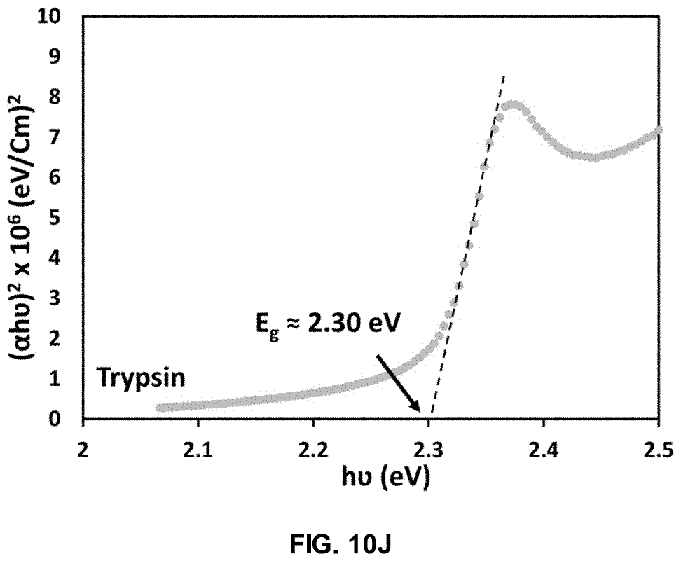

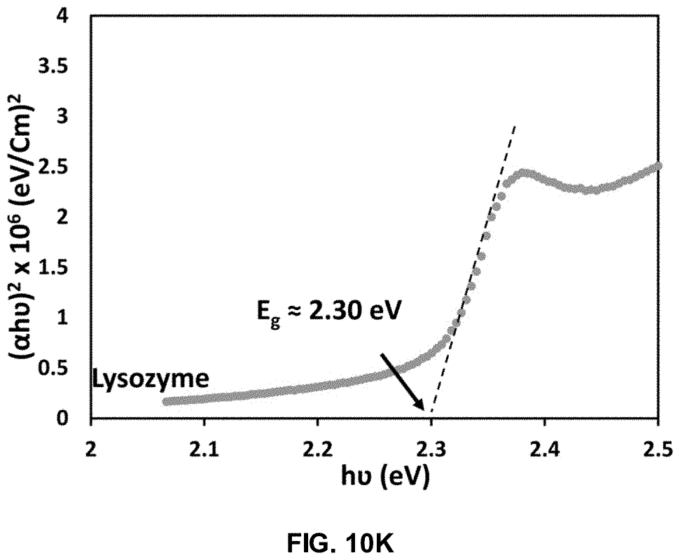

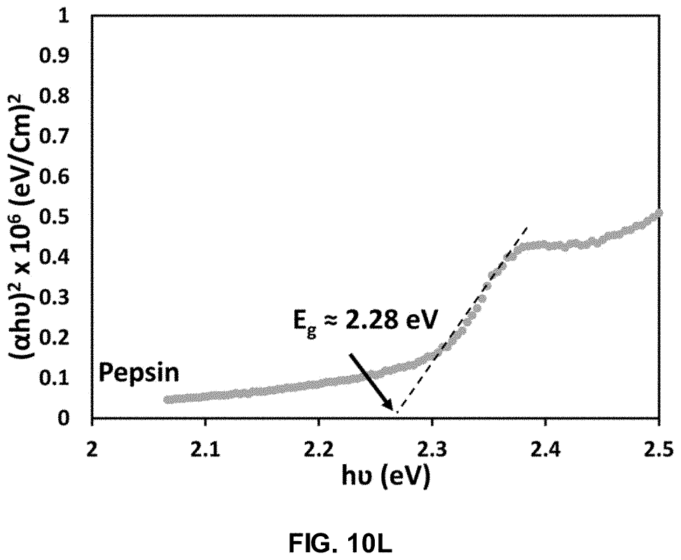

The optical properties (UV-Vis absorption and PL emission) of the HPNCs synthesized were compared with different proteins (FIGS. 8C-8E) to assess each protein's performance as capping agent and HPNC performance enhancer. All protein-HPNCs exhibited similar light absorption in the visible region, with casein having the strongest light absorption amongst all other samples. Meanwhile, the light absorption edges of the protein-HPNCs had a slight redshift compared to casein-HPNCs with the redshift order of casein<BSA<hemoglobin<trypsin=lysozyme<pepsin, which resulted in varying optical band gap from 2.32 eV in the case of casein to 2.28 eV for pepsin (FIGS. 10A-L). To monitor the effect of protein type on the PL emission, PL studies were performed for HPNCs containing fixed protein:perovskite molar (FIG. 8D) or mass ratio (FIG. 8E). In both cases, the PL intensity is the highest for casein-HPNCs, and BSA-HPNCs followed with the second highest PL intensity. The PL intensity further decreased when other proteins were used as capping agents, following the order hemoglobin>lysozyme>trypsin>pepsin for constant mass ratio, and trypsin>lysozyme>hemoglobin>pepsin considering constant molar ratio. Interestingly, negligible PL peak shift occurred using different proteins. In terms of PLQY %, casein-HPNCs possess highest PLQY % of 44-56% followed by BSA-HPNCs and hemoglobin-HPNCs (Table 4). A significantly lower PLQYs of below 15% were obtained for the HPNCs synthesized with other proteins. The effective surface passivation through crosslinking of HPNCs with different ligands (here with proteins) might be one reason of PLQY % variation using different capping agents.

PL lifetime of perovskite NCs is affected by particle size and defect concentrations. The longer PL lifetimes of HPNCs are correlated with HPNCs having larger relative sizes. It is worth mentioning that the surface defects generally behave as nonradiative recombination sites of charge carriers and consequently significantly influence the lifetime of charge carriers. The time-resolved PL decay curves of protein mediated-MAPbBr₃ HPNCs are shown in FIG. 8F. The curves are fitted with a biexponential function of time and the two lifetime components together with average lifetimes are tabulated in Table 4. Casein-HPNCs possessed the longest τₐᵥₑ, extended up to 34.49 ns. The average PL decay order is casein>BSA≥hemoglobin>Lysozyme>trypsin>pepsin within the range of 34.49-3.65 ns in agreement with the presence of nano-sized perovskite crystallites. These values are comparable and, in some cases (i.e. casein-, BSA-, and hemoglobin-HPNCs), longer than that of related systems, such as colloidal MAPbBr₃ nanocrystals with small molecule ligands (˜10.3 ns). In the present case, TEM images (FIGS. 8G-8I) depict that samples had spherical morphologies with the particles size trend of casein-<BSA-<hemoglobin-HPNCs. This is in an inverse agreement with the PL intensity study (FIGS. 8D and 8E) that casein had the highest and hemoglobin had the lowest PL intensity among the three aforementioned samples due to the fact that bigger particles were less stable in colloidal solution and had inferior optical properties (Table 4). In addition, although smaller particles contain higher surface defects, casein-HPNCs have a greater PLQY % than BSA- and hemoglobin-HPNCs. Longer PL lifetime and higher PLQY % of casein-HPNCs suggest a reduction of the nonradiative channels on the surface of NCs. In other words, casein-HPNCs may have fewer surface defects due to a relatively higher grafting density of casein chains on the NCs surface compared with the other protein-HPNCs. The possibility of size control using different proteins has been demonstrated herein. In fact, the size, amino acid sequence, pI, and hydrophobicity of the used proteins can directly alter the size of the NCs. Other possibilities to control the size of the NCs include protein engineering, using proteins with defined cavities (e.g., protein cages) as well as the concentration control of the Pb precursors.

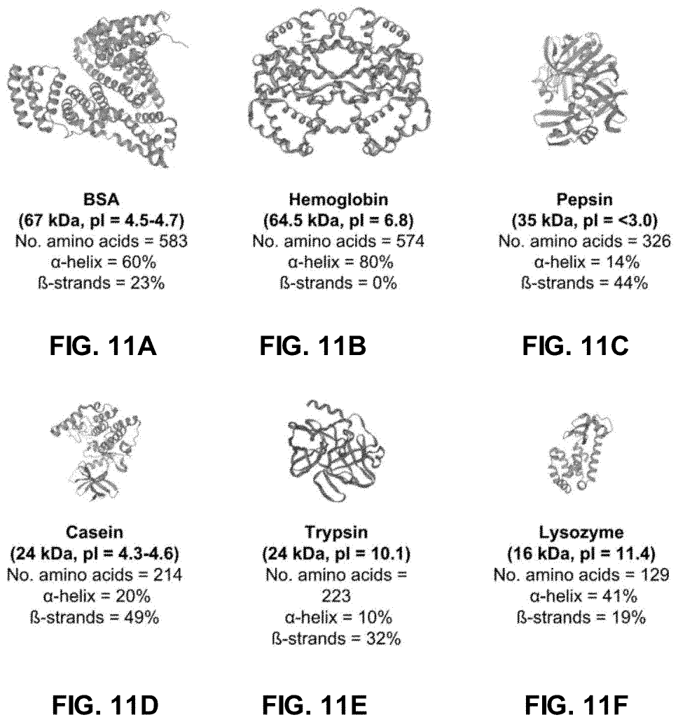

The surface chemistry governs the interactions of proteins-HPNCs and the formation of the nanoparticles. Proteins, as chains of amino acids linked by peptide bonds, can provide a highly dynamic bonding environment due to hydrogen-bonding, π-π stacking, van der Waals, and electrostatic interactions, which promote their integration with the HPNCs surface. The physicochemical properties of different proteins (Table 5 and FIGS. 11A-11F) such as protein size, pI, and hydrophobicity, as well as with specific protein amino acids sequence, amino acids type and protein 3D conformation might have impacts on the interactions of proteins with NCs. For instance, it was previously explained earlier that the pI and protein surface charge are crucial for the electrostatic binding of [PbX₆]⁴⁻ complexes to the protein prior to nucleation and growth of HPNCs. In this study, proteins were selected with increasing pI in the order pepsin<casein<BSA<hemoglobin<trypsin<lysozyme. Only casein and BSA pI values are in mid-acidic region (4.3-4.7) which allows i) for a strong interaction of [PbX₆]⁴⁻ complexes with positively charged protein below their pI and ii) for a highly stable colloidal suspension of HPNCs to form above the pI values. However, pepsin with low pI value, hemoglobin with pI close to neutral pH, and lysozyme and trypsin with basic pI values demonstrate inferior PL emissions. However, pepsin, hemoglobin, lysozyme, and trypsin still demonstrated sufficient and useful PL properties for many applications in aqueous conditions.

TABLE 5
Characteristics of the tested proteins

| | | | | No. of | | |
|---|---|---|---|---|---|---|
| | Molecular | | | amino | α | β |
| Protein | weight | | pI | acids | helix | strands |
| BSA | 67 | kDa | 4.5-4.7 | 583 | 60% | 23% |
| Hemoglobin | 64.5 | kDa | 6.8 | 574 | 80% | 0% |
| Pepsin | 35 | kDa | <3.0 | 326 | 14% | 44% |
| Casein | 24 | kDa | 4.3-4.6 | 214 | 20% | 49% |
| Trypsin | 24 | kDa | 10.1 | 223 | 10% | 32% |
| Lysozyme | 16 | kDa | 11.4 | 129 | 41% | 19% |

Last but not least, surface chemistry significantly affected the optical properties of HPNCs including light absorption, PL emission, and PLQY % as well as charge carriers' lifetime, as is evident in FIGS. 8A-8I and Table 4. Without wishing to be bound by theory, the differences in defect passivation capability of proteins as well as HPNCs-proteins interactions stemmed from the differences in energetic alignments amongst the HPNCs band edges and proteins' amino acids orbitals. In fact, surface defects capture the photoinduced carriers, resulting in the decline of the radiative recombination and deteriorated optical properties. Whereas effective defects passivation of HPNCs, here by applying appropriate protein type, boosts radiative recombination, which is of great importance to increase charge carrier lifetime as an example. Consequently, applying the different tested proteins does not change the crystal structure of HPNCs, but can significantly influence the surface chemistry of HPNCs by proper defect passivation. Moreover, the dielectric constant of surrounding medium of HPNCs could influence their optical properties. Perovskite nanostructures possess inferior charge transport properties than that of bulk HPs because of non-efficient screening of the electron-hole Coulomb interaction. On the other hand, nanoparticles coated with organic ligands around them have smaller dielectric constants resulting in higher exciton binding energy in comparison with bulk HPs, which is advantageous towards a greater PLQY % close to 100% and weaker charge transfer (i.e. the charge confinement and lower defects concentration). Higher local dielectric constant of peptide nucleic acids (PNAs) in comparison with commonly used smaller organic materials is beneficial for perovskite nanoparticles charge transfer. Likewise, proteins can alter the local dielectric constant of HPNCs and eventually influence their optoelectrical properties.

To conclude, the present disclosure has established a green fully aqueous method for the synthesis of highly stable HPNCs using different proteins as capping agents. The protein decorated HPNCs represent optical characteristics, such as bright intense green emission together with charge carrier lifetimes and PLQY %, comparable with conventionally synthesized NCs with organic ligands and solvents. Structural analysis proved the preservation of the internal MAPbBr₃ crystalline part, together with the existence of protein capping agents on the surface of the HPNCs. The pH of the synthesis media, physicochemical properties of the protein ligands as well as surface chemistry of HPNCs have essential impacts on the optical properties of the final products. High colloidal dispersibility and long term stability in ambient conditions of the synthesized protein-HPNCs are favorable for potential future biological and biomedical applications. The established synthesis method here can be extrapolated for other HPs including strongly emitting multiply colored solutions as well as those based on Pb-free compositions. Proteins with specific biological functions could also be introduced in the HPNCs colloids to synthesized bioactive luminescent particles.

### REFERENCES

Eperon, G. E., et al., The Importance of Moisture in Hybrid Lead Halide Perovskite Thin Film Fabrication. Acs Nano, 2015. 9(9): p. 9380-9393.
Jana, A. and K. S. Kim, Water-Stable, Fluorescent Organic Inorganic Hybrid and Fully Inorganic Perovskites. Acs Energy Letters, 2018. 3(9): p. 2120-2126.
Geng, C., et al., Aqueous Synthesis of Methylammonium Lead Halide Perovskite Nanocrystals. Angewandte Chemie-International Edition, 2018. 57(31): p. 9650-9654.
Yang, X. G., L. F. Ma, and D. P. Yan, Facile synthesis of 1D organic-inorganic perovskite micro-belts with high water stability for sensing and photonic applications. Chemical Science, 2019. 10(17): p. 4567-4572.
Shih, Y. C., et al., Amino-Acid-Induced Preferential Orientation of Perovskite Crystals for Enhancing Interfacial Charge Transfer and Photovoltaic Performance. Small, 2017. 13(22).
Lang, A., et al., Bioinspired Molecular Bridging in a Hybrid Perovskite Leads to Enhanced Stability and Tunable Properties. Advanced Functional Materials, 2020. 30(42).
Wang, S. N., et al., Hybrid organic-inorganic lead bromide perovskite supercrystals self-assembled with L-cysteine and their good luminescence properties. Journal of Materials Chemistry C, 2018. 6(41): p. 10994-11001.
Prochazkova, A. J., et al., Cyclic Peptide Stabilized Lead Halide Perovskite Nanoparticles. Scientific Reports, 2019. 9: p. 6.
Sharma, A. K., et al., Essential Amino Acid-Enabled Lead Bromide Perovskite Nanocrystals with High Stability. Particle & Particle Systems Characterization: p. 6.
Li, Z., et al., Recent progress in Pb-free stable inorganic double halide perovskites. Journal of Semiconductors, 39(7), 071003, 2018.
Xu, Q., et al., Perovskite solar absorbers: materials by design. Small Methods, 2(5), 1700316, 2018.
Li, W., et al., Chemically diverse and multifunctional hybrid organic-inorganic perovskites. Nature Reviews Materials, 2(3), 1-18, 2017.
Bi, C. H., et al., Improved Stability and Photodetector Performance of CsPbI3 Perovskite Quantum Dots by Ligand Exchange with Aminoethanethiol. Advanced Functional Materials, 2019. 29(29).
Shamsi, J., et al., Metal Halide Perovskite Nanocrystals: Synthesis, Post-Synthesis Modifications, and Their Optical Properties. Chemical Reviews, 2019. 119(5): p. 3296-3348.
Hamill, J. C., J. Schwartz, and Y. L. Loo, Influence of Solvent Coordination on Hybrid Organic-Inorganic Perovskite Formation. Acs Energy Letters, 2018. 3(1): p. 92-97.
Jing, L. H., et al., Aqueous Based Semiconductor Nanocrystals. Chemical Reviews, 2016. 116(18): p. 10623-10730.

What is claimed is:

1. A protein-halide perovskite nanocrystal (p-HPNC) comprising:
a crystalline core of halide perovskites and an outer layer made of protein surrounding the crystalline core, wherein the protein has a net positive electric charge at a pH of 3 or less in its free state, the protein is linked to the surface of the crystalline core, and wherein the halide perovskites have a formula ABX₃, wherein A is a monovalent cation, B is a divalent cation, and X is a monovalent halide anion.

2. The p-HPNC of claim 1, wherein the protein is linked to the crystalline core by at least one of hydrogen bonds, π-π stacking, van der Waals bonds, and electrostatic interactions.

3. The p-HPNC of claim 1, wherein the outer layer is a capping layer and the protein is a capping protein.

4. The p-HPNC of claim 1, wherein the p-HPNC has a full width at half-maximum (FWHM) of from 10 to 50 nm.

5. The p-HPNC of claim 1, wherein the protein has a molecular weight of from 500 Da to 500 kDa.

6. The p-HPNC of claim 1, wherein the protein has an isoelectric point (pI) in the range of 3-12.

7. The p-HPNC of claim 1, wherein the protein has an isoelectric point (pI) in the range of 3.5-5.5.

8. The p-HPNC of claim 1, wherein the protein is casein.

9. The p-HPNC of claim 8, wherein the p-HPNC has a size of 5 to 50 nm.

10. The p-HPNC of claim 1, wherein X is I⁻, Br⁻ or Cl⁻.

11. The p-HPNC of claim 1, wherein the crystalline core is a cubic phase or a tetragonal phase.

12. An aqueous colloidal suspension comprising p-HPNC colloids, wherein the p-HPNC is as defined in claim 1, and wherein the aqueous colloidal suspension has a pH of less than 7.

13. The aqueous colloidal suspension of claim 12, wherein the pH is equal to or less than 6.

14. A method of producing an aqueous colloidal suspension comprising p-HPNC colloids, the method comprising:
mixing in an acidic aqueous solution a divalent cation B, a monovalent halide anion X, and a protein, to obtain a dispersion comprising the divalent cation B, the monovalent halide anion X, and the protein;
mixing in the dispersion a monovalent cation A, and increasing the pH of the dispersion to obtain the p-HPNC colloids and the aqueous colloidal suspension.

15. The method of claim 14, wherein the monovalent cation A is selected from Cs⁺, CH₃NH₃⁺, and CH(NH₂)₂⁺.

16. The method of claim 14, wherein X is selected from Br⁻, I⁻ and Cl⁻.

17. The method of claim 14, wherein the divalent cation B is selected from Pb²⁺, Sn²⁺, and Ge²⁺.

18. The method of claim 14, wherein the acidic aqueous solution has a pH of less than 3.

19. The method of claim 14, wherein the method is performed at ambient conditions of temperature and pressure.

20. An imaging method comprising: irradiating the aqueous colloidal suspension as defined in claim 12 with a light irradiation, and measuring the photoluminescence.
